(19) United States
(12) Patent Application Publication
(10) Pub. No.: US 2009/0052259 A1
(43) Pub. Date: Feb. 26, 2009

(54) NON-VOLATILE SEMICONDUCTOR MEMORY DEVICE

(75) Inventors: Tsuyoshi ARIGANE, Akishima (JP); Digh Hisamoto, Kokubunji (JP); Yasuhiro Shimamoto, Tokorozawa (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/194,433

(22) Filed: Aug. 19, 2008

(30) Foreign Application Priority Data
Aug. 24, 2007 (JP) JP 2007-218516
Jun. 11, 2008 (JP) JP2008-153112

(51) Int. Cl. G11C 11/34

(52) U.S. Cl. 365/185.29

(57) ABSTRACT

A non-volatile semiconductor memory device is provided. A gate electrode configuring a memory cell is turned into floating state and a potential of a gate electrode adjacent thereto is changed, and reduce the potential of the gate electrode by this change of potential and the capacitive coupling. Furthermore, charge sharing is carried out by connecting two gate electrodes, and the voltage of the gate electrode is reduced by capacitive coupling with another gate electrode adjacent thereto, to largely reduce the potential of the gate electrode. Thereby, the voltage level generated by the charge pump circuit can be reduced. As a result, the size of the charge pump circuit can be reduced, or the circuit itself can be eliminated, resulting in reduction of the chip area.

### CROSS-REFERENCE TO RELATED APPLICATION

The present application claims priorities from Japanese Patent Application No. JP 2007-218516 filed on Aug. 24, 2007, and Japanese Patent Application No. JP 2008-153112 filed on Jun. 11, 2008, the contents of which are hereby incorporated by reference into this application.

### TECHNICAL FIELD OF THE INVENTION

The present invention relates to a semiconductor circuit device, and in particular to technology that can effectively reduce the area of a chip by reducing the size of power supply circuit.

### BACKGROUND OF THE INVENTION

Non-volatile semiconductor memory devices such as a Flash EPROM (Electrically Erasable and Programmable ROM) have been developed as a high-density storage medium for a mobile terminal, a digital camera, and mobile computer cards. In order to use a memory cells as storage medium as above, cost reduction by higher degree of integration and reduction of power consumption are necessary. Especially, reduction of power consumption is essential for a flash memory because the memory needs rewriting of a lot of data at the same time in a highly integrated circuit.

A conventional flash memory incorporates a charge pump circuit or a booster circuit that generates voltage higher than power supply voltage, for write/erase operation of a cell. This charge pump circuit uses an MOS transistor as a switch constituting a charging path and a discharging path, applies input power via the charging path to a charging capacitor to accumulate charges, applies input power via the discharging path to the charging capacitor to add charges, and transfers the total charges to an output capacitor to boost the voltage. In order to provide high operating voltage for a memory, charge pump circuits connected in many stages are necessary. This configuration inevitably increases the circuit area. The higher the memory operating voltage is, the larger the area occupied by the charge pump circuits is. Therefore, memory operation with less voltage generated by the charge pump circuit is important for the reduction of the chip area and power consumption.

Japanese Patent Application Laid-Open Publication No. 2004-186452 (Patent Document 1) discloses a technique of the erase operation by applying negative voltage to a memory gate in a split gate type memory cell at erase operation. In this operation, a negative power supply is necessary to apply negative voltage. There are two kinds of charge pump: a charge pump circuit for positive power supply and that for negative power supply. In the traditional erase operation, only a charge pump circuit for a negative power supply is used for generation of negative power supply. Therefore, a large charge pump circuit that can provide negative power supply which is high enough for the erase operation is required.

The applicant investigated currently available prior documents relating to the subject of the present invention, and found following documents.

Japanese Patent Application Laid-Open Publication No. H11-163306 (Patent Document 2) discloses a technique to boost the voltage of a word line by capacitive coupling, by forming a boosting plate on a word line, and increasing the voltage applied to the boosting gate at the time of program operation, in a NAND flash memory.

Japanese Patent Application Laid-Open Publication No. 2006-302411 (Patent Document 3) discloses a method to boost the potential of a selection word line by capacitive coupling between two adjacent word lines, by applying write voltage to a selection word line, and applying boosting voltage to a write non-selection word line adjacent thereto, in a NAND flash memory.

Japanese Patent Application Laid-Open Publication No. 2003-151290 (Patent Document 4) discloses a method to boost the selection gate potential to a potential high enough for the read operation, by capacitive coupling between selection gate word lines in a twin MONOS (Metal-Oxide-Nitride-Oxide-Semiconductor) memory cell.

Japanese Patent Application Laid-Open Publication No. 2005-285185 (Patent Document 5) discloses a technique to reduce CR delay of a word line, by turning a word line adjacent thereto into floating state, in a NAND flash memory.

### SUMMARY OF THE INVENTION

In the technique disclosed in Patent Document 1, a charge pump circuit for negative power supply that is large enough to reach erase voltage is necessary. Even when the size of memory cells in a memory cell array region is decreased, a large charge pump circuit is necessary if the erase voltage remains same. Therefore, further reduction in size of a memory cell does not lead to reduction in the area occupied by the charge pump circuit for negative power supply. It is difficult to decrease the chip area efficiently only by reduction of the size of a memory cell array according to reduction of size of the memory cell.

The methods disclosed in the Patent Documents 2 to 4 are used in programming or read operation. They are not applicable for the erase operation using a negative voltage. These documents have no disclosure of invention for a charge pump circuit for negative power supply. Therefore, even if the methods are applied to the technique disclosed in Patent Document 1, the area of a charge pump for positive voltage supply may be decreased, but that of a charge pump for negative voltage supply cannot be decreased.

The methods disclosed in the Patent Documents 2 to 4 can reduce the area of a circuit, by eliminating a charge pump circuit for boosting voltage and boosting the potential of a desired gate electrode by capacitive coupling between adjacent gate electrodes. For example, boosting of the potential of the gate electrode G1 by change in the potential of the gate electrode G2 can be expressed as follows.

(Boosting of the potential of the gate electrode G1)=(capacitive coupling ratio of the gate electrode G1 to the gate electrode G2)×(change in the potential of the gate electrode G2).

In these methods, the area of charge pump circuit necessary for the boosting can be cut. However, in the above equation, (capacitive coupling ratio of the gate electrode G1 to the gate electrode G2) is defined by the structure of the memory cell. In order to raise (boosting of the potential of the gate electrode G1), (change in the potential of the gate electrode G2) must be raised. Thus, the range of voltage that can be boosted is limited.

An object of the present invention is to provide a non-volatile semiconductor memory device with small chip area, by reducing the area of a charge pump circuit for negative voltage supply in a memory cell that uses negative voltage for the erase operation.

Another object of the invention is to provide a non-volatile semiconductor memory device with small chip area, by reducing not only the area of a charge pump circuit for negative power supply but also that of a charge pump circuit for positive and negative power supply, by widening the range of voltage that can be boosted. In a conventional configuration, the range of voltage is limited by the structure of the memory cell and the amount of the change in the potential of the gate electrode G2.

The above and other objects and novel characteristics of the present invention will be apparent from the description of this specification and the accompanying drawings.

The typical ones of the inventions disclosed in this application will be briefly described as follows.

A non-volatile semiconductor memory device according to the present invention comprises: a semiconductor substrate; a first charge accumulation film formed on the semiconductor substrate; a first gate electrode formed on the first charge accumulation film; a second gate electrode formed adjacent to the first gate electrode; and a control circuit to control the potential of the first and second gate electrodes, wherein, at the time of data erase operation which corresponds to the amount of charges accumulated in the first charge accumulation film, the control circuit operates to supply a first potential to the first gate electrode and a second potential to the second gate electrode respectively, thereafter, the control circuit operates to turn the first gate electrode into floating state, and, thereafter, the control circuit operates to supply a fourth potential lower than the second potential to the second gate electrode so as to make the first gate electrode have a third potential lower than the first potential.

A non-volatile semiconductor memory device according to another aspect of the present invention comprises: a semiconductor substrate; a first charge accumulation film formed on the semiconductor substrate; a first gate electrode formed on the first charge accumulation film; a second gate electrode formed adjacent to the first gate electrode; a second charge accumulation film formed on the semiconductor substrate; a third gate electrode formed on the second charge accumulation film; a fourth gate electrode formed adjacent to the third gate electrode; and a control circuit to control the potential of the first, second, third and fourth electrodes, wherein, at rewrite operation of the data corresponding to the charges accumulated in the second charge accumulation film, the control circuit operates to supply a first potential to the first gate electrode, a second potential to the second gate electrode, a third potential to the third date electrode and a fourth potential to the forth gate electrode respectively, the control circuit operates to turn the first and third gate electrodes into floating state, the control circuit operates to supply a sixth potential to the second gate electrode to make the first gate electrode have a fifth potential, thereafter, the control circuit operates to electrically connect the first and third gate electrodes to make the first and third gate electrodes have a seventh potential which is an intermediate potential between the third and sixth potentials, thereafter, the control circuit operates to electrically disconnect the third and first gate electrodes to turn the first and third gate electrodes into floating state, thereafter, the control circuit operates to supply a ninth potential to the fourth gate electrode to make the third gate electrode have an eighth potential, the ninth potential is higher than the fourth potential when the sixth potential is higher than the second potential, and, the ninth potential is lower than the forth potential when the sixth potential is lower than the second potential.

A non-volatile semiconductor memory device according to other aspect of the present invention comprises: a semiconductor substrate; a first charge accumulation film formed on the semiconductor substrate; a first gate electrode formed on the first charge accumulation film; a second gate electrode formed adjacent to the first gate electrode; a second charge accumulation film formed on the semiconductor substrate; a third gate electrode formed on the second charge accumulation film; a fourth gate electrode formed adjacent to the third gate electrode; a first switch to turn the first gate electrode into floating state; and a second switch to turn the second gate electrode into floating state.

The effects obtained by typical aspects of the present invention will be briefly described below.

In the non-volatile semiconductor memory device according to the invention disclosed in the present application, the size of a charge pump circuit for negative power supply can be reduced, or the charge pump circuit itself can be eliminated, and the size of a charge pump circuit for positive power supply can be reduced. As a result, the area of the chip can be reduced.

### BRIEF DESCRIPTIONS OF THE DRAWINGS

FIG. 1 is a block diagram showing a non-volatile semiconductor memory device according to the first embodiment of the present invention;

FIG. 2 is a cross-sectional view showing a memory cell in the non-volatile semiconductor memory device according to the first embodiment;

FIG. 3 is a top view showing a part of connection region between two adjacent memory gates according to the first embodiment;

FIG. 4 is an equivalent circuit diagram of the switch transistor region in which the memory gate is in floating state according to the first embodiment;

FIG. 5 is an equivalent circuit diagram of the switch transistor region to connect a memory gate to another memory gate according to the first embodiment;

FIG. 6 is a timing chart showing the erase operation of the non-volatile semiconductor memory device according to the first embodiment;

FIG. 7 is a diagram showing the erase operation of FIG. 6;

FIG. 8 is a diagram showing a step subsequent to FIG. 7 in the sequence of the erase operation of FIG. 6;

FIG. 9 is a diagram showing a step subsequent to FIG. 8 in the sequence of the erase operation of FIG. 6;

FIG. 10 is a diagram showing a step subsequent to FIG. 9 in the sequence of the erase operation of FIG. 6;

FIG. 11 is a diagram showing a step subsequent to FIG. 10 in the sequence of the erase operation of FIG. 6;

FIG. 12 is a timing chart showing the erase operation of the non-volatile semiconductor memory device according to the second embodiment of the present invention;

FIG. 13 is an equivalent circuit diagram of the switch transistor region in which the memory gate is in floating state according to the third embodiment of the present invention;

FIG. 14 is an equivalent circuit diagram of the switch transistor region to connect a memory gate to another memory gate according to the third embodiment;

FIG. 15 is a timing chart showing the erase operation of the non-volatile semiconductor memory device according to the third embodiment;

FIG. 16 is a diagram showing the erase operation of FIG. 15;

FIG. 17 is a diagram showing a step subsequent to FIG. 16 in the sequence of the erase operation of FIG. 15;

FIG. 18 is a diagram showing a step subsequent to FIG. 17 in the sequence of the erase operation of FIG. 15;

FIG. 19 is a diagram showing a step subsequent to FIG. 18 in the sequence of the erase operation of FIG. 15;

FIG. 20 is a diagram showing a step subsequent to FIG. 19 in the sequence of the erase operation of FIG. 15;

FIG. 21 is a diagram showing a step subsequent to FIG. 20 in the sequence of the erase operation of FIG. 15;

FIG. 22 is a diagram showing a step subsequent to FIG. 21 in the sequence of the erase operation of FIG. 15;

FIG. 23 is a diagram showing a step subsequent to FIG. 22 in the sequence of the erase operation of FIG. 15;

FIG. 24 is a diagram showing a step subsequent to FIG. 23 in the sequence of the erase operation of FIG. 15;

FIG. 25 is a cross-sectional view showing a memory cell in the non-volatile semiconductor memory device according to the fourth embodiment of the present invention;

FIG. 26 is a top view showing a part of connection region between two adjacent memory gates according to the fourth embodiment;

FIG. 27 is an equivalent circuit diagram of the switch transistor region in which the memory gate is in floating state according to the fourth embodiment;

FIG. 28 is an equivalent circuit diagram of the switch transistor region to connect a memory gate to another memory gate according to the first embodiment;

FIG. 29 is an equivalent circuit diagram of the switch transistor region in which a selection gate is in floating state according to the fourth embodiment;

FIG. 30 is a timing chart showing the erase operation of the non-volatile semiconductor memory device according to the fourth embodiment;

FIG. 31 is a diagram showing the erase operation of FIG. 30;

FIG. 32 is a diagram showing a step subsequent to FIG. 31 in the sequence of the erase operation of FIG. 30;

FIG. 33 is a diagram showing a step subsequent to FIG. 32 in the sequence of the erase operation of FIG. 30;

FIG. 34 is a diagram showing a step subsequent to FIG. 33 in the sequence of the erase operation of FIG. 30;

FIG. 35 is a diagram showing a step subsequent to FIG. 34 in the sequence of the erase operation of FIG. 30;

FIG. 36 is a diagram showing a step subsequent to FIG. 35 in the sequence of the erase operation of FIG. 30;

FIG. 37 is a top view showing a part of connection region between two adjacent memory gates according to the fifth embodiment;

FIG. 38 is an equivalent circuit diagram of the switch transistor region in which a word line is in floating state according to the fifth embodiment;

FIG. 39 is an equivalent circuit diagram of the switch transistor region to connect the word line to another word line according to the fifth embodiment;

FIG. 40 is a timing chart showing the erase operation of the non-volatile semiconductor memory device according to the fifth embodiment of the present invention;

FIG. 41 is a diagram showing the erase operation of FIG. 40;

FIG. 42 is a diagram showing a step subsequent to FIG. 41 in the sequence of the erase operation of FIG. 40;

FIG. 43 is a diagram showing a step subsequent to FIG. 42 in the sequence of the erase operation of FIG. 40;

FIG. 44 is a diagram showing a step subsequent to FIG. 43 in the sequence of the erase operation of FIG. 40;

FIG. 45 is a diagram showing a step subsequent to FIG. 44 in the sequence of the erase operation of FIG. 40;

FIG. 46 is an explanatory view showing a memory cell in the non-volatile semiconductor memory device according to the sixth embodiment of the present invention;

FIG. 47 is a diagram showing an example of a memory cell array structure according to the seventh embodiment;

FIG. 48 is a diagram that schematically shows a switch transistor connecting the memory blocks in one memory mat in FIG. 47;

FIG. 49 is an equivalent circuit diagram containing the switch transistor shown in FIG. 48;

FIG. 50 is a timing chart showing a part of the erase operation of the non-volatile semiconductor memory device according to the seventh embodiment;

FIG. 51 is a diagram showing an example of the memory cell array structure according to the eighth embodiment;

FIG. 52 is an equivalent circuit diagram containing the switch transistor shown in FIG. 51;

FIG. 53 is a timing chart showing a part of the erase operation of the non-volatile semiconductor memory device according to the eighth embodiment;

FIG. 54 is an equivalent circuit diagram of a memory cell array containing a switch transistor of the non-volatile semiconductor memory device according to the ninth embodiment;

FIG. 55 is a timing chart showing a part of the erase operation of the non-volatile semiconductor memory device according to the ninth embodiment;

FIG. 56 is a diagram showing an erase current per cell necessary for the erase operation using FN tunnel current, and that for the erase operation using band-to-band tunneling, in the non-volatile semiconductor memory device according to the tenth embodiment;

FIG. 57 is a diagram showing an example of a switch transistor structure according to the twelfth embodiment; and

FIG. 58 is a diagram showing an example of a switch transistor structure according to the thirteenth embodiment.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment.

### First Embodiment

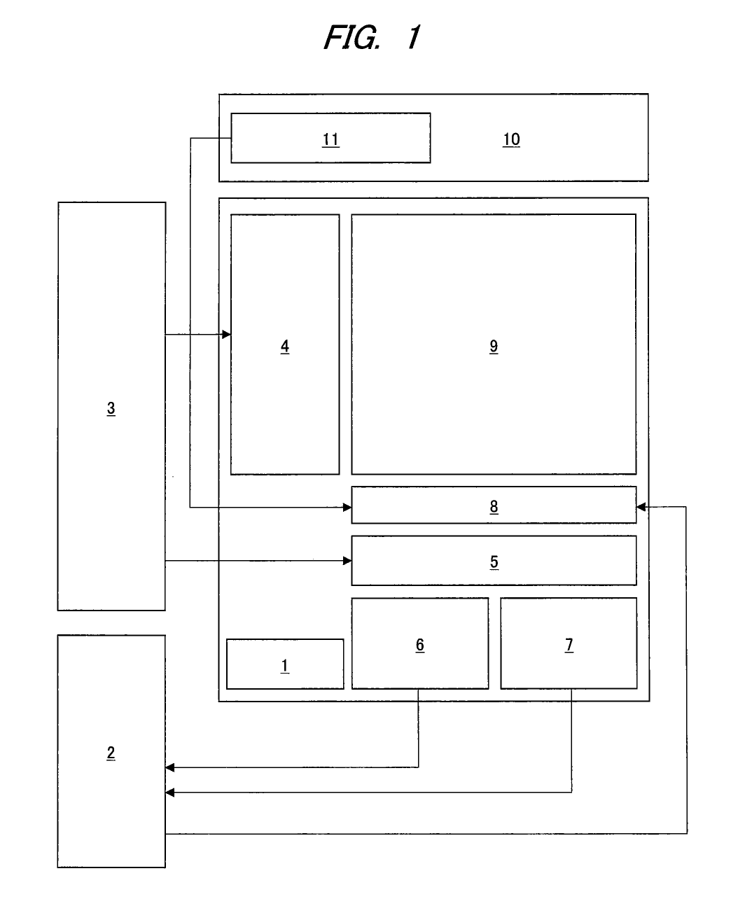

FIG. 1 is a block diagram showing a non-volatile semiconductor memory device according to a first embodiment of the present invention. The non-volatile semiconductor memory device according to the first embodiment comprises a control circuit 1, an I/O circuit 2, an address buffer 3, a row decoder 4, a column decoder 5, a verify sense amplifier circuit 6, a high-speed read sense amplifier circuit 7, a write circuit 8, a memory cell array 9 and a power supply circuit 10. The control circuit 1 temporarily stores control signals inputted from a host such as a microcomputer connected thereto, to control operating logic. The control circuit 1 controls the potential of the gate electrodes of the memory cells in the memory cell array 9, as will be described later. Various data is inputted/outputted to and from the I/O circuit 2, including data to be read from and written in the memory cell array 9, and program data. The address buffer 3 temporarily stores addresses inputted from an external device.

The row decoder 4 and the column decoder 5 are connected to the address buffer 3. The row decoder 4 carries out decoding based on the row address outputted from the address buffer 3, and the column decoder 5 carries out decoding based on the column address outputted from the address buffer 3. The verify sense amplifier circuit 6 verifies the erase/write operation, and the high-speed read sense amplifier circuit 7 reads data used in the read operation. The write circuit 8 latches the write data inputted through the I/O circuit 2, and controls the data write operation. The power supply circuit 10 comprises a voltage generating circuit that generates various voltages used at the time of write, erase and verify operations or the like, and a current trimming circuit 11 that generates and supplies arbitrary voltage to the write circuit.

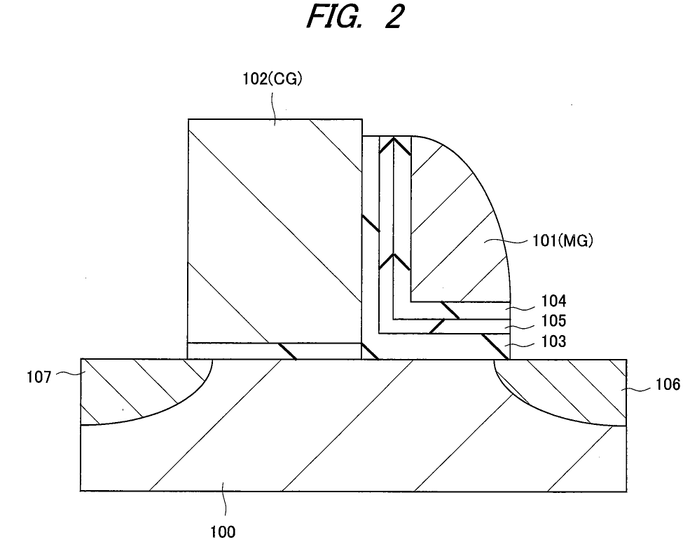

The memory cell array 9 comprises memory cells regularly arranged like an array therein as a minimum unit of memory. FIG. 2 is a cross-sectional view of the memory cells provided in this memory cell array 9. The memory cell comprises a gate electrode 101 (MG) (memory gate) that operates the memory, and a gate electrode 102 (CG) that selects a cell (selection gate, control gate), on a silicon substrate 100. The gate dielectric of the memory gate has MONOS (Metal-Oxide-Nitride-Oxide-Semiconductor) structure that comprises two oxide silicon films 103 and 104, and a nitride silicon film 105 placed between the oxide silicon films 103 and 104 for accumulating charge to be operated by injecting/discharging charges to the silicon nitride film 105.

The capacitance between the gates, as well as the capacitive coupling ratio of the memory gate to the selection gate, are large (for example, capacitive coupling ratio: 0.8) since the memory gate and the selection gate are parallel to each other in the memory cell array 9. In the figure, reference numerals 106 and 107 designate diffusion layers of the memory cell.

Next, as basic operations of the memory cell, operations of (1) write, (2) erase and (3) read will be described. In this specification, an operation to increase charges in the charge accumulation film is called the write operation, while that to decrease charges is called the erase operation. In the first embodiment, a memory cell comprising n-channel MOS will be described for illustrative purpose. However, same principle can be applied to a memory cell comprising a p-channel MOS.

(1) At the time of the write operation, a positive potential (4.5V) is given to the diffusion layer 106 on the memory gate side, and a ground potential same as that of the substrate is given to the diffusion layer 107 on the selection gate side. A high gate overdrive voltage (10V) is applied to the memory gate 101 to turn the channel under the memory gate into ON state. The potential of the selection gate 102 is higher than the threshold by 0.1V or 0.2V for example to turn into ON state. Under this voltage condition, a strong electric field is generated in the channel region under the memory gate and the selection gate, and many hot electrons are generated. The write operation is carried out by injecting some part of the generated hot electrons into the memory gate side. Generally, this procedure is known as source side injection (SSI).

(2) At the erase operation, a negative potential (−6V) is given to the memory gate (gate electrode 101) and positive potential (6V) is given to the diffusion layer 106 on the memory gate side. Thereby, strong inversion and band-to-band tunneling phenomenon occur in the region where the memory gate at the end of the diffusion layer and the diffusion layer 106 overlap, to generate holes. In the memory cell, the generated holes are accelerated in the channel direction, attracted by bias in the memory gate, injected into the nitride silicon film 105, to carry out erase operation. That is, the threshold of the memory gate that has been elevated by hot electron injection is lowered by hole injection to carry out the erase operation

(3) At the read operation, a positive potential (1.5V) is given to the diffusion layer 107 on the selection gate side, and a positive potential (1.5V) is given to the selection gate 102 to turn the channel under the selection gate into ON state. Under this condition, a memory gate potential (for example, 0V) sufficient enough to determine difference in the thresholds of the memory gates given by write/erase condition is applied. Current flows through the channel of the memory gate in the write condition, while it does not flow in the erase condition. By this procedure, it can be determined whether the memory cell is in the write condition or the erase condition, by amount of the current flowing through the channel of the memory gate.

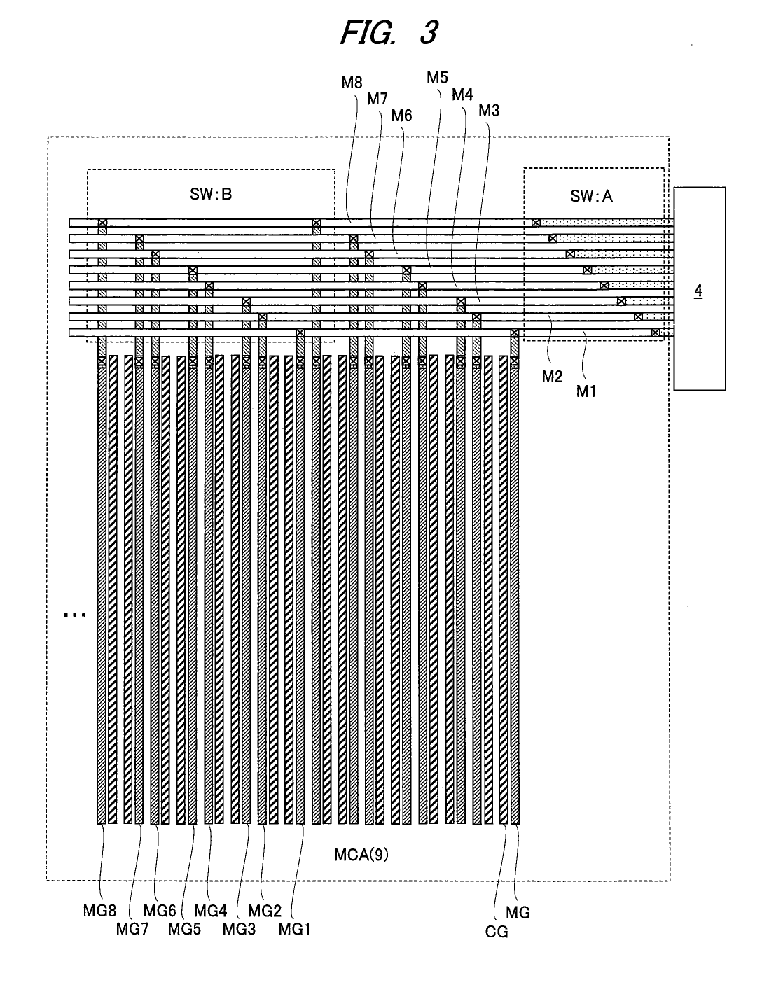

FIG. 3 is a top view showing a part of the contact region between two adjacent memory gates in the memory cell array 9 (MCA) according to the first embodiment. In the memory cell array MCA, the memory gates MG and the selection gates CG shown in FIG. 2 are arranged regularly, and these memory gates MG and selection gates CG serve as common gates for two or more memory cells. The memory cell array 9 (MCA) comprise a switch transistor A (SW:A) region that connects/disconnects the memory gate MG and the row decoder 4, and a switch transistor B (SW:B) region that connects/disconnects two memory gates MG. When the switch transistor in the switch transistor A (SW:A) region is turned into OFF state, the memory gate MG can be turned into floating state. In the array in FIG. 3, the memory gates MG1 to MG8 are connected to the metal wirings M1 to M8, respectively, and one in every eight memory gate MG is electrically connected to the contact and metal wiring (M1 to M8). The memory gate MG connected can be controlled by the potential of one metal wiring. In this specification, one metal wiring is called one system. FIG. 3 shows an example with 8 systems, wherein each wiring connects to one in every eight memory gates MG. The voltage of these eight wiring systems (M1-M8) can be controlled one by one. The potential of the selection gates CG can be controlled one by one.

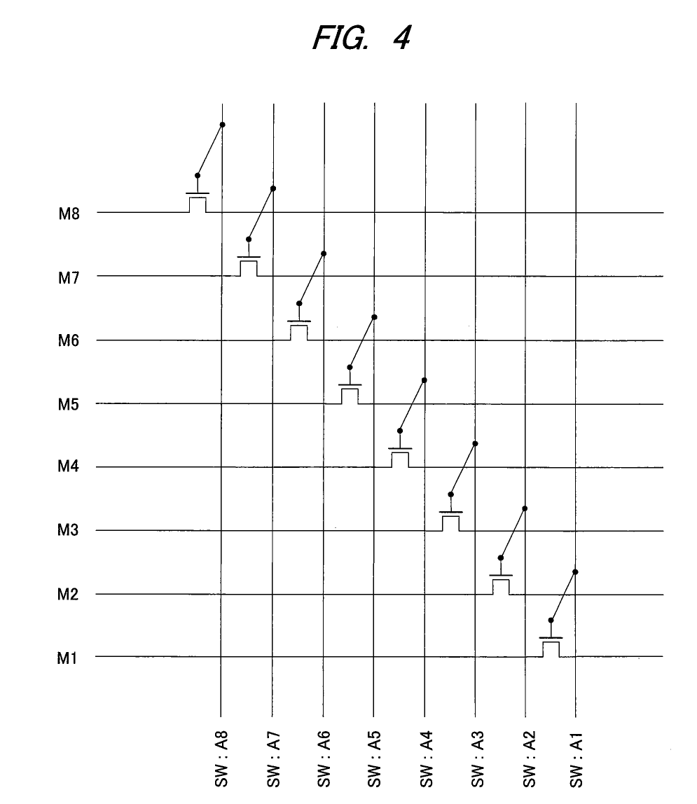

FIG. 4 is an equivalent circuit diagram of the switch transistor A (SW:A) region. The metal wirings M1 to M8 are respectively connected to the memory gates MG1 to MG8 that are the systems 1 to 8 of FIG. 3. The metal wirings M1 to M8 respectively comprises switch transistors that can electrically connect/disconnect the memory gates MG1 to MG8 and the row decoder 4 in FIG. 3. The gate electrodes of the switch transistors are connected to wirings SW:A1 to SW:A8 respectively and can be controlled one by one. For example, the current flowing state/floating state of the system 1 that controls the memory gate MG1 is controlled by ON/OFF of the switch transistor A1 (a switch transistor connected to the wiring SW:A1).

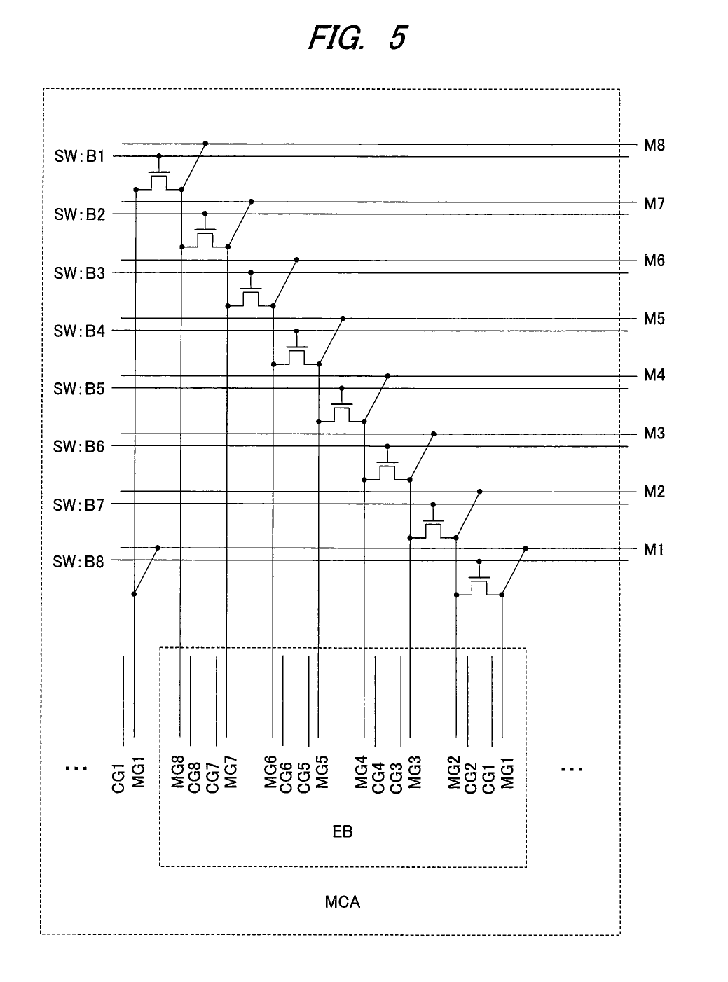

FIG. 5 is an equivalent circuit diagram of the switch transistor B (SW:B) region. The metal wirings M1 to M8 are the metal wirings M1 to M8 in FIG. 3. The metal wirings M1 and M2 are connected via a source and a drain of a transistor. As shown in the figure, the metal wirings M2 and M3, the metal wirings M3 and M4, the metal wirings M5 and M6, the metal wirings M6 and M7, the metal wirings M7 and M8 and the metal wiring M8 and M1 are connected by different transistors, respectively. In this structure, the memory gates MG1 and MG can be electrically connected/disconnected by ON/OFF of the transistor. The gates of the transistors are connected to wirings SW:B1 to SW:B8, respectively, to control ON/OFF of the transistor. An erase block EB is shown in the memory cell array MCA. In this specification, an erase block comprises one set of memory gates MG1 to MG8.

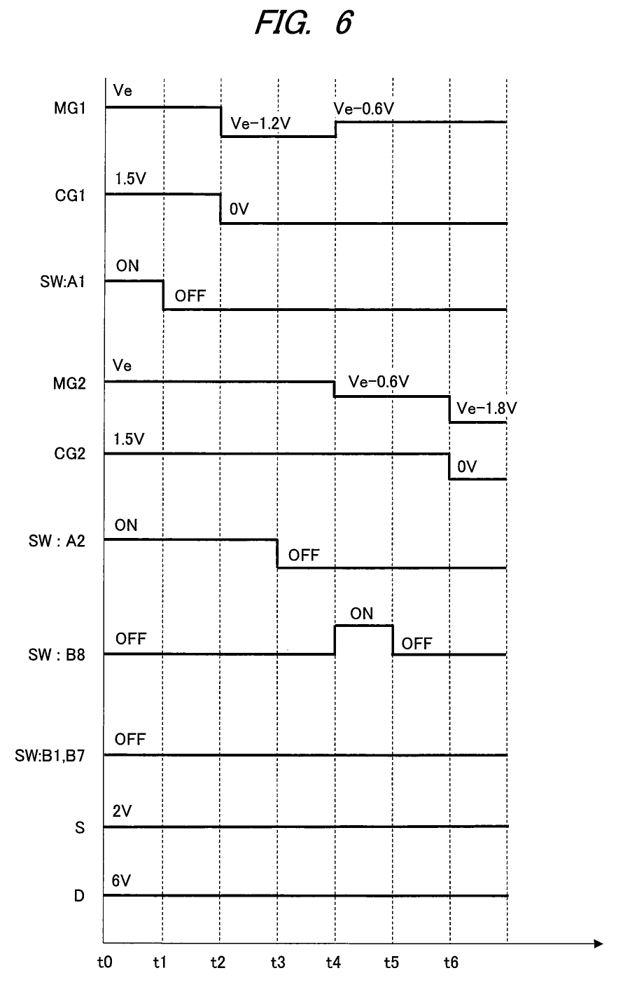

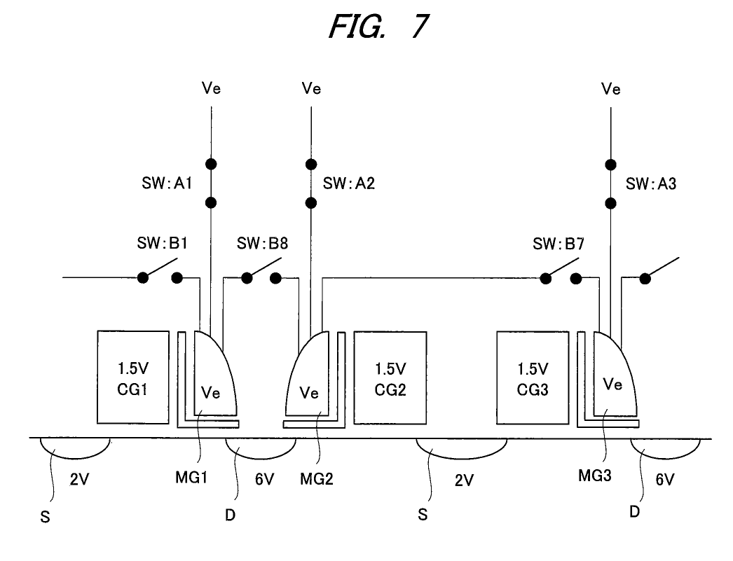

FIG. 6 is a timing chart showing a part of the erase operation of the non-volatile semiconductor memory device according to the first embodiment. FIGS. 7 to 11 illustrate the erase operation thereof. The memory cell to be erased is a memory cell containing the memory gate MG1 or MG2. The term “the voltage reduction” used in this specification means that when the voltage is negative, its absolute value is changed from small value to large value. In the embodiment of the present specification, unless specifically stated, voltage supply to the memory gates and the selection gates and on/off operation of the switch transistors are carried out by the operation of the control circuit 1 shown in FIG. 1.

To make clear the position of the sequence of FIG. 6, description will be made with reference to FIG. 7. FIG. 7 is a cross-sectional view of a part of the substrate in the direction perpendicular to the direction in which the memory gates MG and the selection gates CG are arranged. FIG. 7 shows the memory gates MG1 to MG3 and the selection gates CG1 to CG3. In FIG. 7, one memory cell comprises the memory gate MG1 and the selection gate CG1, as shown in FIG. 2. S and D designate a source region and a drain region of the memory cell, respectively, that are diffusion layers. For convenience, FIG. 7 also shows transistors SW:A1 (A1) to SW:A3 (A3), SW:B1 (B1) and SW:B7 (B7) to SW:B8 (B8) that is arranged in the switching transistor regions A and B of FIG. 3. Transistors are designated by same reference symbols as the wirings. FIG. 6 shows the operating waveform from the beginning to the end of the erase operation. The connection between the electrodes of the memory cell at each time will be described with reference to FIGS. 7 to 11.

First, at time to, a voltage of 6V is applied to the diffusion layer (drain region D) on the memory cell side, while a voltage of 2V is applied to the diffusion layer (source region S) on the selection gate side. The switch transistors A1 (SW:A1) and A2 (SW:A2) that control current flowing state/floating state of the memory gates MG1 and MG2 are in ON state, current flows through the memory gates MG1 and MG2 and the row decoder, and a voltage of Ve for the erase operation (for example, −4.8V) is applied to the both gates. A voltage of 1.5V is applied to the selection gates CG1 and CG2 that are adjacent to the memory gates MG1 and MG2. The switch transistor B8 (SW:B8) that connects the memory gates MG1 and MG2 is in OFF state. Under this condition, the voltage applied to the diffusion layer on the selection gate side is higher than that applied to the selection gate. Thus, the transistor containing the selection gate is in OFF state (FIG. 7).

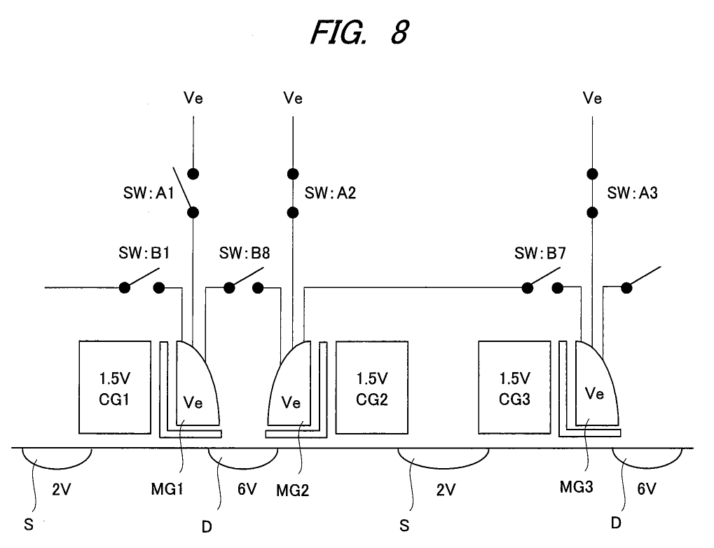

At time t1, the switch transistor A1 (SW:A1) is turned into OFF state to turn the memory gate MG1 into floating state (FIG. 8).

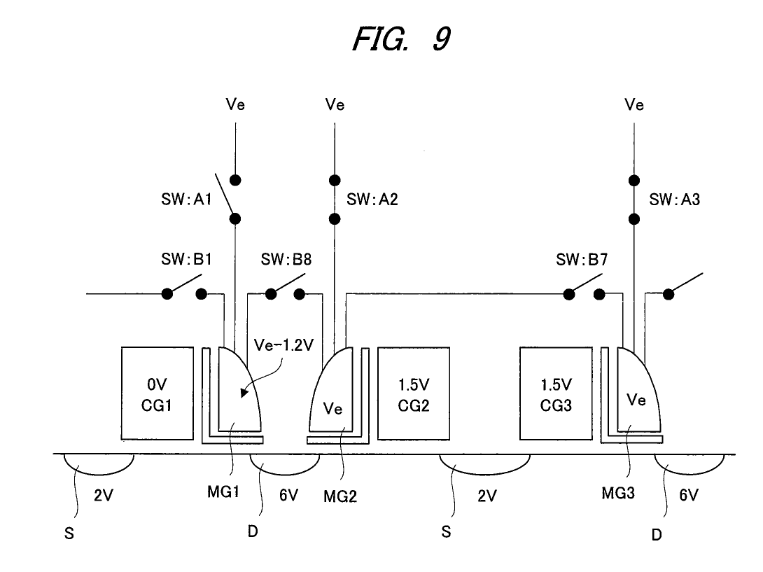

At time t2, a voltage of 0V is applied to the selection gate CG1, and the electrode potential of the memory gate MG1 is reduced according to the capacitive coupling ratio (0.8) and change in the selection gate voltage (1.5V) (reduced portion: 0.8×1.5=1.2V) (FIG. 9).

As described above, by using the capacitive coupling between the memory gate MG1 and the selection gate CG1, the voltage of Ve for the erase operation can be increased from −6V to −4.8V for example. Thus, the area of the charge pump circuit for negative voltage supply can be reduced. In a configuration where erase voltage is applied to the memory gate for the erase operation, the chip area can be reduced according to the present invention.

In the following, a method to further reduce the voltage of the memory gate MG (MG2) to the negative direction will be described.

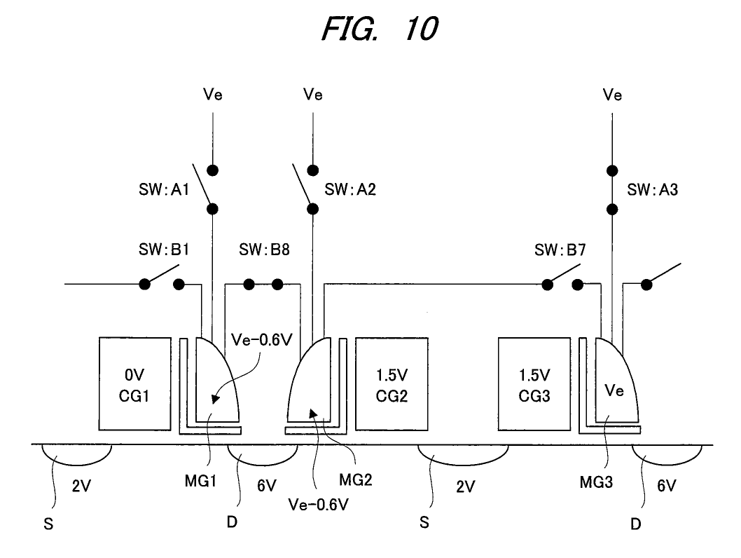

At time t3, the switch transistor A2 (SW:A2) is turned into OFF state to turn the memory gate MG2 into floating state. At time t4, the switch transistor B8 (SW:B8) connecting the memory gates MG1 and MG2 is turned into ON state to electrically connect the memory gates MG1 and MG2. Thereby, the charges stored in the memory gates MG1 and MG2 are shared. At this time, the charge sharing makes the electrode potential between the both gates equal. Thus, the electrode potential of the memory gate MG2 is reduced from the initially applied a voltage of Ve, by half (1.2/2=0.6V) of the reduction by the operation at time t2 (Ve−0.6V) (FIG. 10).

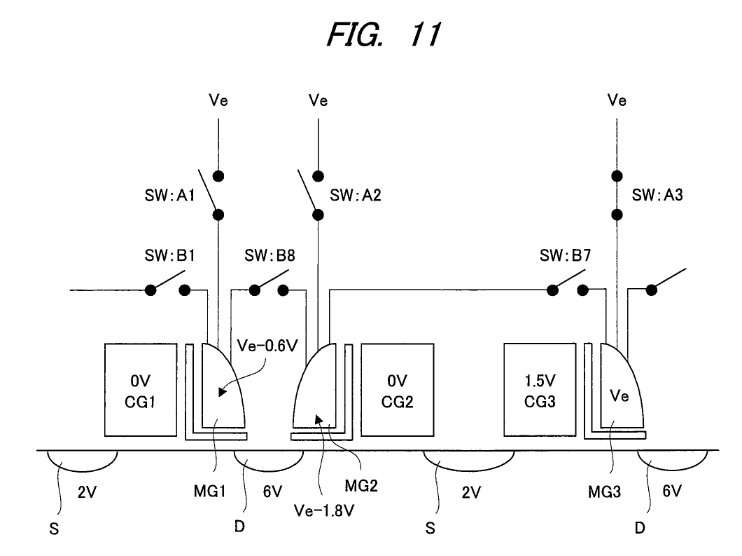

At time 5, the switch transistor B8 (SW:B8) is turned into OFF state to electrically disconnect the memory gates MG1 and MG2. At time t6, a voltage of 0V is applied to the selection gate CG2. The electrode potential of the memory gate MG2 is reduced to (Ve−1.8V), according to the capacitive coupling ratio (0.8) and the change in selection gate voltage (1.5V) (reduced portion: 0.8×1.5=1.2V) (FIG. 11). As described, by the charge sharing and capacitive coupling, a potential change larger than the voltage change by (capacitive coupling ratio)×(change in selection gate voltage) can be obtained. This technique further reduces the area of the charge pump circuit for generating negative voltage.

According to the first embodiment, the memory gate MG is controlled by eight systems in the memory cell array. Further voltage reduction in the negative direction is possible by repeating voltage reduction using the charge sharing between the memory gates, the memory gate floating, and the capacitive coupling ratio of adjacent selection gates, for the memory gates MG3 to MG8, in the sequence similar to that shown in FIG. 6. For example, when this procedure is repeated for the memory cells connected to all eight systems, charge sharing between the memory gates MG8 and MG1 is option. Therefore, at least seven times of the charge sharing steps, seven times of memory gate floating steps and eight times of the voltage reduction steps are necessary.

By the erase operation according to the sequence as above, the memory gate electrode can have high potential even when the charge pump circuit for negative voltage supply generates only small voltage. As a result, the size of the charge pump circuit can be reduced, which, in turn, reduces the chip area.

When a voltage of 0V is generated, the charge pump circuit for negative voltage supply outside of a memory array region is not necessary. The chip area can be reduced by the area occupied by the charge pump circuit for negative voltage supply.

Alternatively, when erase voltage of −1.2V for example, is used at the memory gate in the steps till t2 before the charge sharing, this voltage of −1.2V can be generated at the memory gate by generating a voltage of 0V. Thereby, similar to the above configuration, a charge pump circuit for negative voltage supply is not necessary, and the chip area can be reduced by the area occupied by the charge pump circuit for negative voltage supply.

That is, in the embodiment described above, a part or all the role of the charge pump circuit for negative voltage supply can be played by the memory cell in the memory array region, thus, the chip area as a whole can be reduced.

In the first embodiment, the memory cell is a split gate type where a memory gate and a selection gate are disposed via a thin dielectric. It has a capacitive coupling ratio as high as 0.8, so that the negative voltage can be efficiently reduced to the negative side. In other words, since the split gate type memory cell has larger capacitive coupling ratio for same voltage change, one procedure can bring about large voltage reduction. As will be described in other embodiments, above mentioned effect is not limited to the split gate type memory cells. As will be described in other embodiments, same effect can be obtained in a single gate memory cell when the space between the gate electrodes of adjacent memory cells is small due to miniaturization, because this arrangement has high capacitive coupling ratio.

In a split gate type memory cell as described in the first embodiment, the channel directly under the selection gate is in OFF state at the erase operation. Under this condition, unintended off-leak current flows between the source and the drain. In such a case, by reducing the voltage of the selection gate from 1.5V to 0V (operation to reduce the voltage of the memory gate), the OFF state is enhanced and the off-leak current can be suppressed.

In the sequence according to the first embodiment, since the electrode potential of the memory gate is lowered at every charge sharing, the electrode potential of the memory gate MG8 can be markedly reduced and the speed of the erase operation is further improved. By applying appropriate voltage of Ve is to the memory gate initially, the erase operation can be carried out using the electrode potential of the memory gates MG1 to MG7 during the voltage reduction step. This configuration can preferably be used for block-by-block erase operation where memory gates MG1 to MG8 constitute an erase block (or mat-by-mat erase operation, a mat comprising a plurality of blocks). In other words, already decreased negative potential is used for the erase operation of another memory cell, and this operation is repeated. Thus this configuration allows for rapid erase operation that needs large negative voltage. When a memory mat comprises systems of the memory gates MG1 to MG8, the memory cells in the memory mat can be erased efficiently and rapidly. That is, all the memory cells in a memory mat can be erased efficiently and rapidly.

In the sequence of the first embodiment, after the switch transistor A1 (SW:A1) is turned into OFF state, then the switch transistor A2 (SW:A2) is turned into OFF state. But, the turn off operation is not necessarily carried out in this order. For example, the switch transistors A1 (SW:A1) and A2 (SW:A2) can be turned into OFF state simultaneously. In other words, in the first embodiment, the memory gate is enough to be in a floating state when the potential of the adjacent selection gate is reduced, so the adjacent memory gate is enough to be in a floating state when the selection gate is reduced. For example, when the switch transistors A1 (SW:A1) and A2 (SW:A2) are turned into OFF state at the same time, separate gate electrodes of the switch transistors as shown in FIG. 4 are not necessary, instead, a common gate electrode can be used. This configuration reduces the number of the gate electrodes, and the area occupied by the switch transistors, as well. Use of common gate electrode is not limited to the switch transistors A1 (SW:A1) and A2 (SW:A2). All of the switch transistors A1 (SW:A1) to A8 (SW:A8) can share a common gate electrode. Such configuration further reduces the area of switch transistor regions.

When each of the metal wirings M1 to M8 is provided with independent switch transistors A1 (SW:A1) to A8 (SW:A8) respectively as shown in FIG. 4, a voltage can be supplied to a memory gate while another memory gate is in floating state. Therefore, already reduced voltage of a memory gate in floating state (for example, the memory gate MG1) can be returned to the initial voltage of Ve by connecting the memory gate MG1 to an external circuit for voltage supply, while another memory gate (for example, the memory gate MG2) is in floating state. Then the voltage of the adjacent selection gate CG1 is boosted, the memory gate MG1 is turned into floating state again and the voltage of the selection gate CG1 is reduced, to generate voltage lower than a voltage of Ve again. When the switch transistors A1 (SW:A1) to A8 (SW:A8) use common gate electrode, the switch transistors A1 (SW:A1) to A8 (Sw:A8) are turned into OFF state to turn all the memory gates MG1 to MG8 into floating state, and the voltage reduction and the charge sharing are carried out from the system 1. Once the voltage has been reduced from the system 1 to the system 8, the system 8 has no further system to charge. Therefore, the charge sharing and the voltage reduction end at the system 8. On the other hand, when the memory gates respectively comprise switch transistors for turning into floating state, even if the reduction is made to the system 8, the charge sharing and the voltage reduction can be carried out for the system 8 and another system (for example, system 1) again. The operation does not end at the system 8, instead, further the voltage reduction is possible. As a result, this structure can generate further lower negative voltage.

As described, in the first embodiment, since a memory gate comprises a special switch transistor to turn the memory gate potential into floating state, the memory gate potential can be turned into floating state, and the voltage reduction as above is possible. Thereby, the area of the charge pump circuit for negative voltage supply can be reduced, and the area of the chip can be reduced.

In the first embodiment, since the memory gates respectively comprise the switches to turn the potential thereof into floating state as mentioned above, the voltage reduction and the charge sharing can be repeated regardless of the number of the systems. When the voltage reduction is repeated, the effect of the reduction is enhanced, making further reduction in the area of charge pump circuit for negative voltage supply possible.

In the first embodiment, the switch transistors B1 (SW:B1) to B8 (SW:B2) are provided between the memory gates to electrically connect/disconnect the memory gates from each other. Thus, the memory gates can share charges therebetween as mentioned above. By using the charge sharing and the voltage reduction in combination, large negative voltage can be generated, and the area of the charge pump circuit for negative voltage supply can be reduced.

When two or more bit information is stored in one memory cell, the threshold window must be wide compared to the configuration where one bit information is stored in one memory cell. In order to erase a memory cell having large threshold window in same time, higher erase voltage needs to be applied. The power supply circuit according to the invention can provide a larger erase voltage to a similar circuit, thus, it can be preferable used for the erase operation of multi-valued memory cell.

In the above description, the voltage generated by the charge pump for the erase operation is reduced by reducing electrode potential. According to further aspect of the present invention, the voltage applied to the selection gate CG can be shifted from 0V to 1.5V to boost the electrode potential of the memory gate. By charge sharing of the boosted electrode potential between the memory gates and capacitive coupling, the voltage is boosted in positive direction. This change in potential is larger than that obtained by (capacitive coupling ratio)×(change in selection gate voltage). Thus, besides reduction of negative voltage, the voltage generated by the charge pump circuit for the write operation can also be reduced. In this configuration, a memory gate controlled by eight systems can be used to repeat the charge sharing and the voltage boosting. Thereby, efficient and rapid write operation in all memory cells in a memory mat is possible.

### Second Embodiment

The memory cell and array configuration of a second embodiment is similar to that of the first embodiment, except the sequence to boost (or reduce) the desired potential of an electrode using a gate electrode.

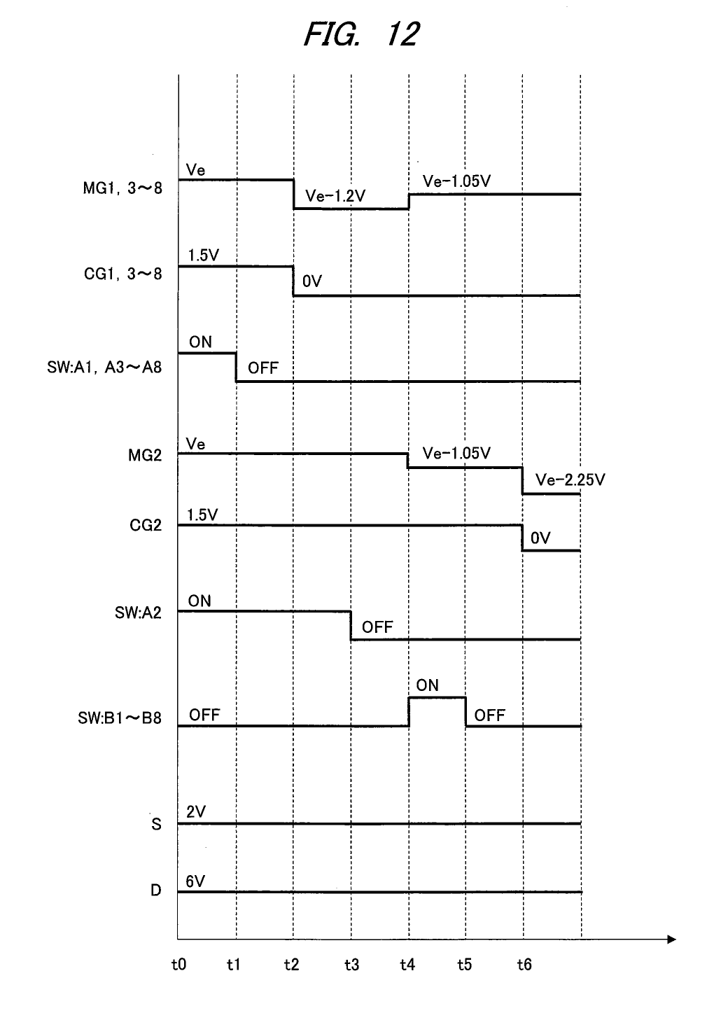

FIG. 12 is a timing chart showing a part of the erase operation in a non-volatile semiconductor memory device according to the second embodiment. The difference from the timing chart of FIG. 6 for the first embodiment is as follows. In the configuration shown in FIG. 6, the potential of the memory gate MG1 is changed using capacitive coupling ratio between the memory gate MG1 and the selection gate CG1, then the charge sharing is carried out between the memory gates MG1 and MG2. In the configuration shown in FIG. 12, the electrode potential of seven systems except the memory gate MG2 (memory gates MG1, and MG3 to MG8) are changed at the same time using the selection gates CG1 and CG3 to CG8 respectively adjacent thereto, then the switch transistors B1 (SW:B1) to B8 (SW:B8) are turned into ON state at the same time to carry out the charge sharing.

Since the charge sharing makes the electrode potential equal, when the charge sharing is carried out for eight systems at the same time, the electrode potential of the memory gate MG2 is reduced by ⅞ (namely, 0.8×1.5×⅞=1.05V) of the reduction at time t2 in FIG. 12. Larger reduction of the electrode potential can be obtained in a shorter sequence than the first embodiment. Therefore, like the first embodiment, the size of the charge pump circuit and the chip area can be reduced. Furthermore, erase time can be shortened compared to the first embodiment for the memory gate MG2.

### Third Embodiment

The difference between the non-volatile semiconductor memory device according to the first embodiment and that according to a third embodiment is the structure of switch transistors A (SW:A) and B (SW:B) shown in FIG. 3.

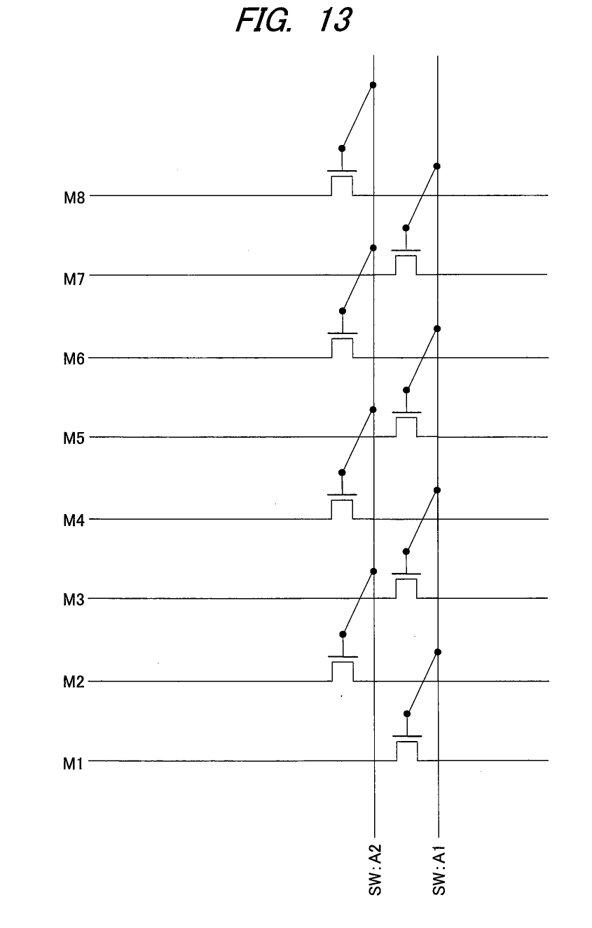

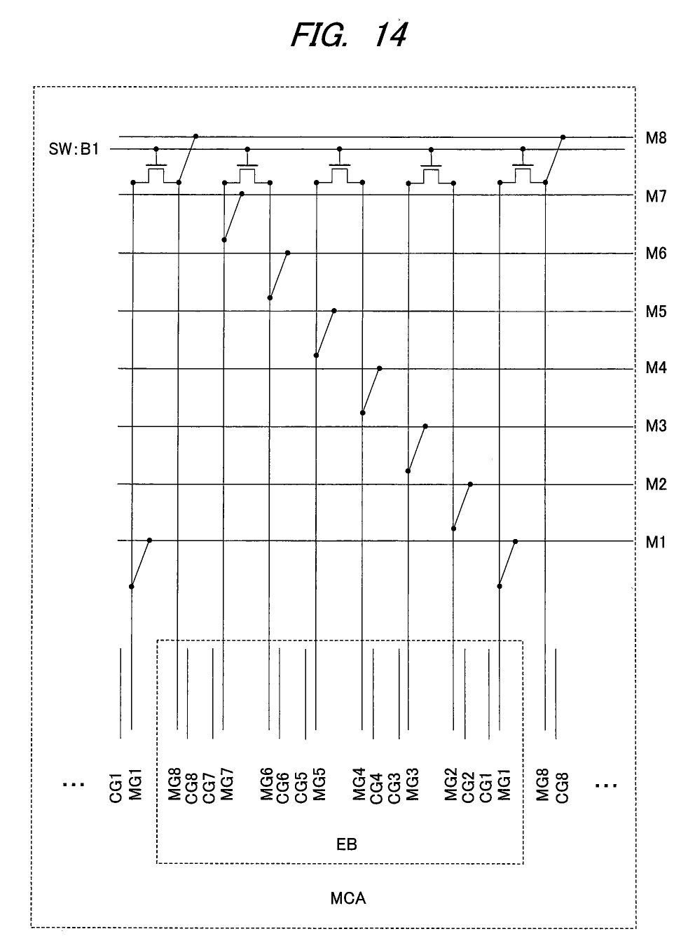

In the first embodiment, eight systems of switch transistors A (SW:A) and B (SW:B) are provided for eight systems of memory gates MG1 to MG8, respectively. In the third embodiment, two systems of switch transistors A (SW:A) and one system of switch transistors B (SW:B) are provided. FIGS. 13 and 14 are equivalent circuit diagrams showing the switch transistor A region that turns the memory gate into current flowing state/floating state, and the switch transistor B region that connects two memory gates. As shown in FIG. 13, the odd-numbered memory gates of the eight systems are connected to the switch transistor A1 (SW:A1), and the even-numbered memory gates are connected to the switch transistor A2 (SW:A2). As shown in FIG. 14, the switch transistor B1 (SW:B1) is a switch which simultaneously connects/disconnects the memory gates MG adjacent to each other.

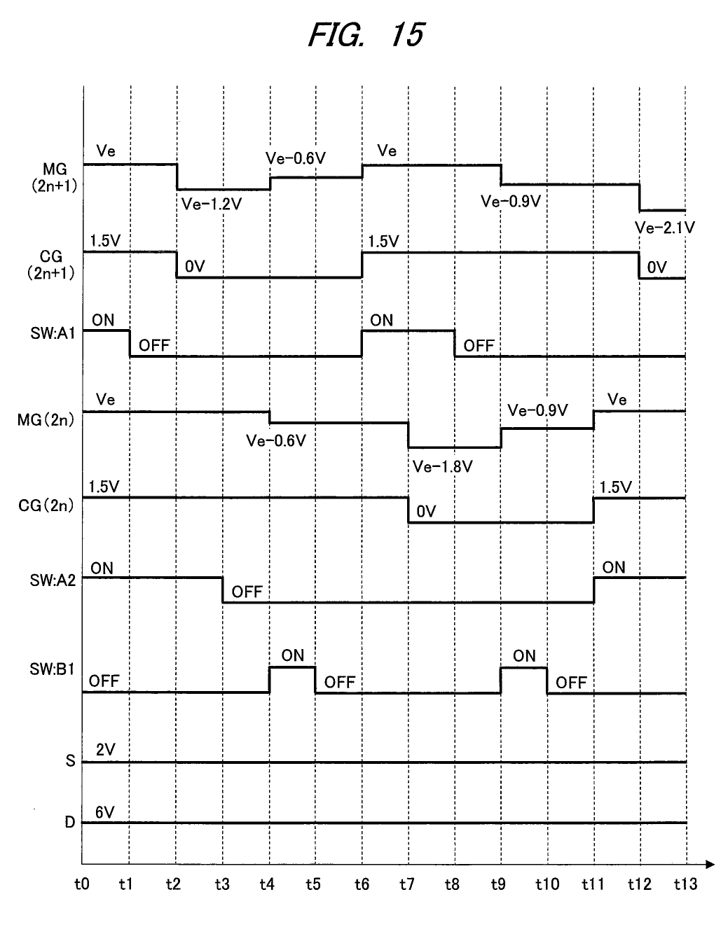

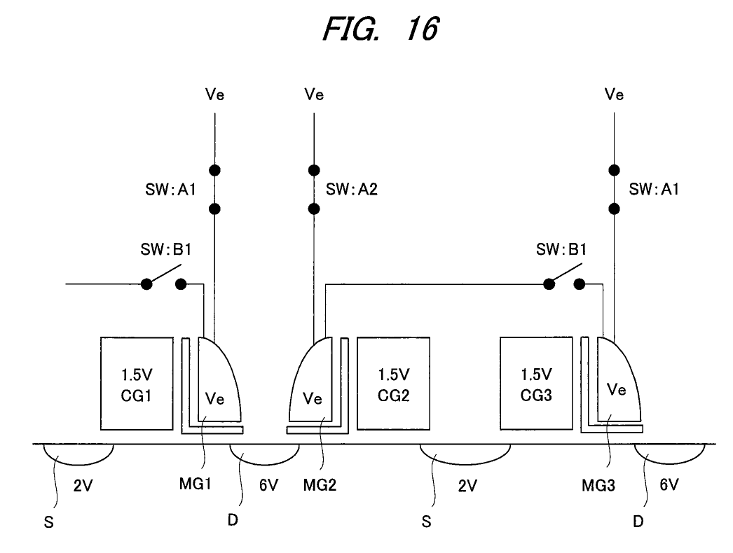

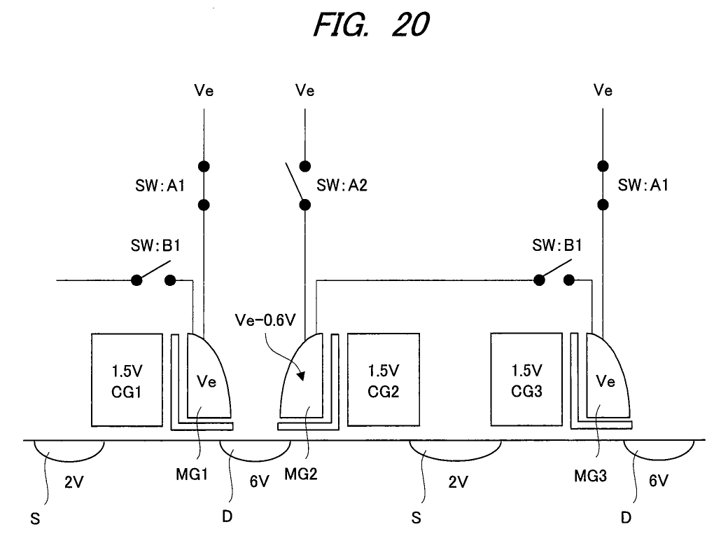

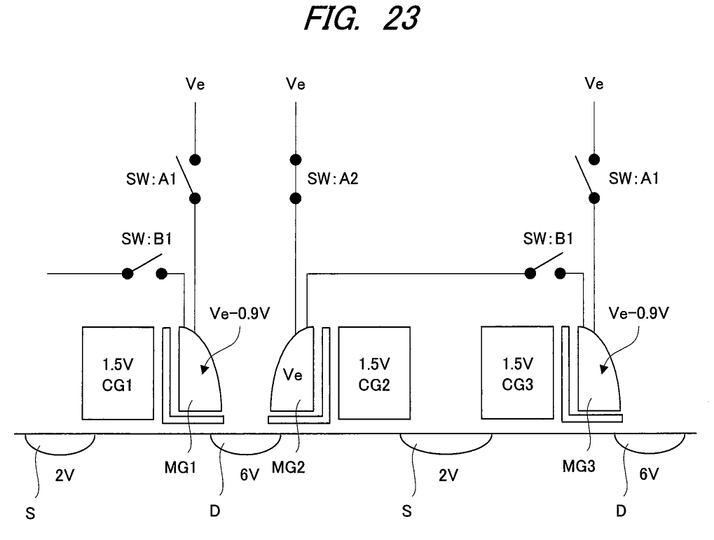

FIG. 15 is a timing chart showing a part of the erase operation of the non-volatile semiconductor memory device according to the third embodiment. FIGS. 16 to 24 are figures for describing the erase operation.

At time t0, a voltage of 6V is applied to the diffusion layer (drain region D) on the memory cell side, while a voltage of 2V is applied to the diffusion layer (source region S) on the selection gate side. The switch transistors A1 (SW:A1) and A2 (SW:A2) that control current flowing state/floating state of the odd-numbered memory gates MG (2n+1) and the even-numbered memory gates MG (2n), respectively, are in ON state. Both systems are in current flowing state, and voltage of Ve (for example, −4.8V) for the erase operation is applied to the both gates. A voltage of 1.5V is applied to the selection gates CG (2n+1) adjacent to the odd-numbered memory gates and the selection gates CG (2n) adjacent to the even-numbered memory gates. The switch transistor B1 (SW:B1) is in OFF state. Under the above voltage applying condition, since the voltage applied to the diffusion layer on the selection gate side is higher than that applied to the selection gate, the selection gate is in OFF state (FIG. 16).

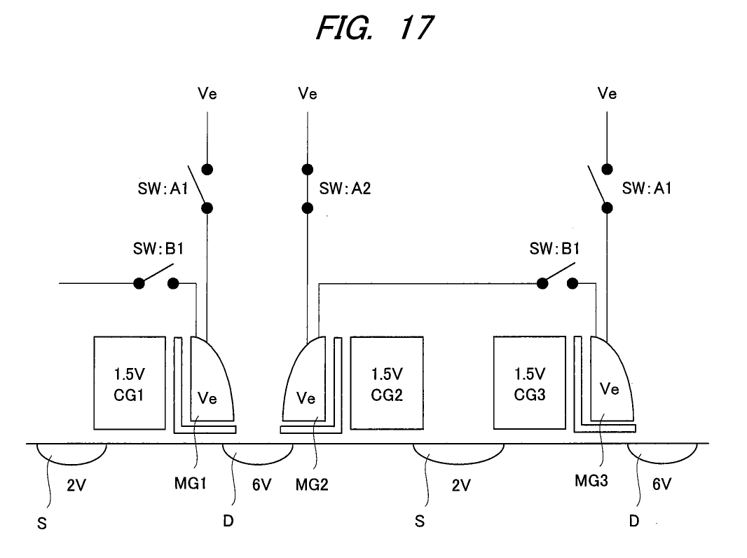

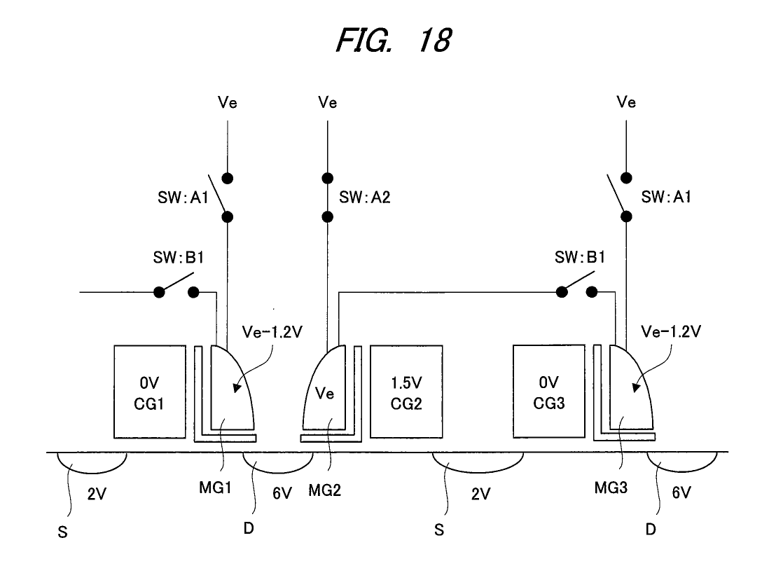

At time t1, the switch transistor A1 (SW:A1) is turned into OFF state to turn the memory gate MG (2n+1) into floating state (FIG. 17). At time t2, a voltage of 0V is applied to the selection gates CG (2n+1), then the electrode potential of the memory gates MG (2n+1) is lowered according to the capacitive coupling ratio (0.8) and change in the voltage of the selection gate (1.5V) (reduced portion: 0.8×1.5=1.2V) (FIG. 18).

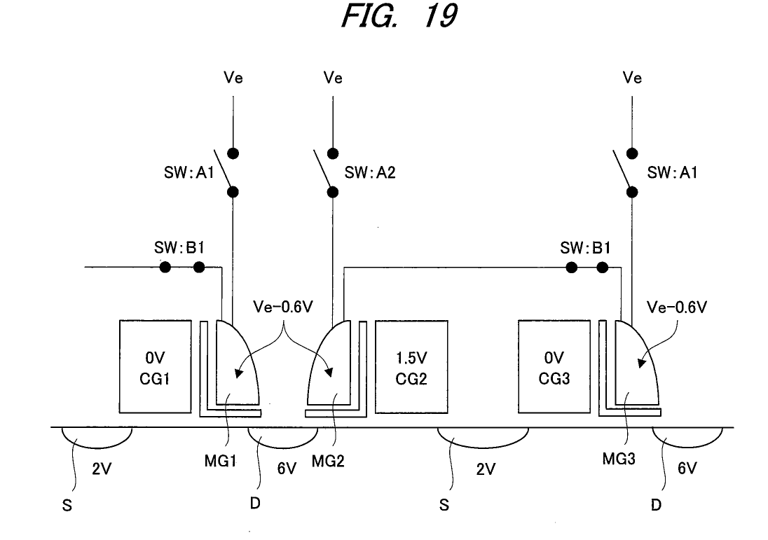

At time t3, the switch transistor A2 (SW:A2) is turned into OFF state to turn the memory gate MG (2n) into floating state. At time t4, the switch transistor B1 (SW:B1) is turned into ON state to share the charges accumulated in the memory gates MG (2n+1) and MG (2n). Since the charge sharing makes the electrode potential between the both gates equal, the electrode potential of the memory gate MG (2n) is reduced to (Ve−0.6V) from the initially applied voltage of Ve, by half (1.2/2=0.6V) of the reduced portion at time t2 (FIG. 19).

At time t5, the switch transistor B1 (SW:B1) is turned into OFF state to disconnect the memory gates MG (2n+1) and MG (2n). At time t6, the switch transistor A1 (SW:A1) is turned into ON state to apply a voltage of Ve to the memory gate MG (2n+1). At the same time, a voltage of 1.5V is applied to the selection gate CG (2n+1).

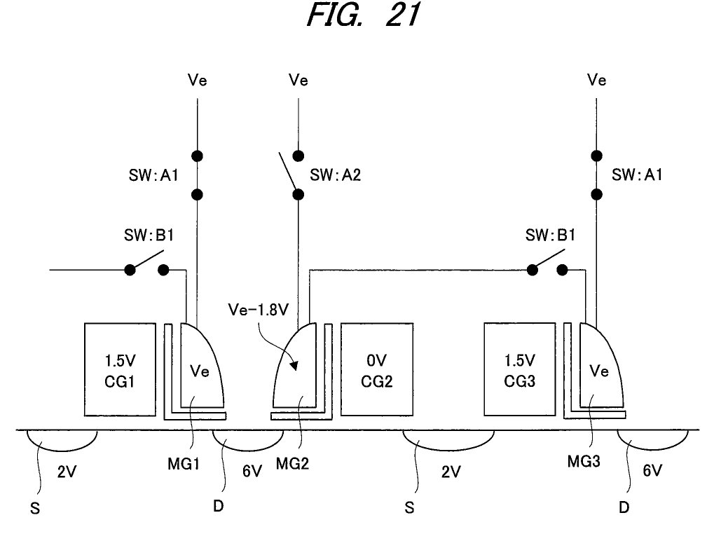

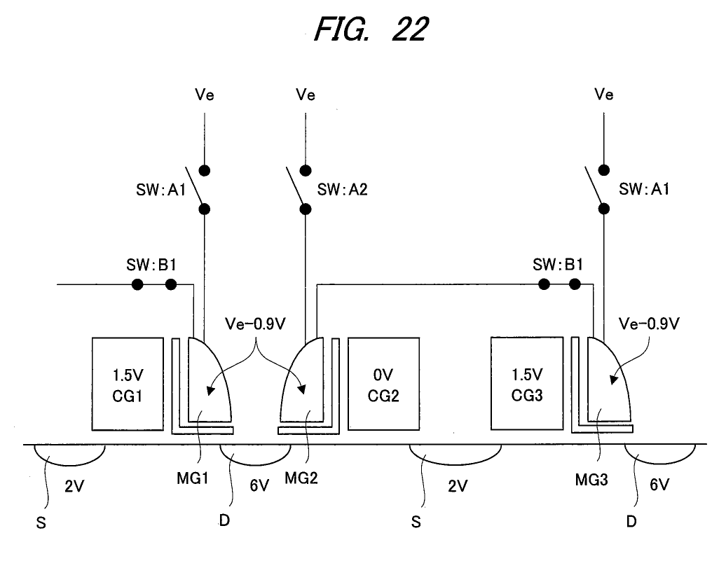

At time t7, the potential of the selection gate CG (2n) is reduced to 0V to reduce the electrode potential of the memory gate MG (2n) to (Ve−1.8V) (FIG. 21). At time t8, the switch transistor A1 (SW:A1) is turned into OFF state to turn the memory gate MG (2n+1) into floating state. After that, at time t9, the switch transistor B1 (SW:B1) is turned into ON state to share the charges between the memory gates MG (2n+1) and MG (2n). The potential of the memory gates MG (2n) and MG (2n+1) becomes (Ve−0.9V) (FIG. 22).

After that, at time t10, the switch transistor B1 (SW:B1) is turned into OFF state to disconnect the memory gates MG (2n+1) and MG (2n). At time t11, the switch transistor A2 (SW:A2) is turned into ON state to apply a voltage of Ve to the memory gate MG (2n). At the same time, a voltage of 1.5V is applied to the selection gate CG (2n).

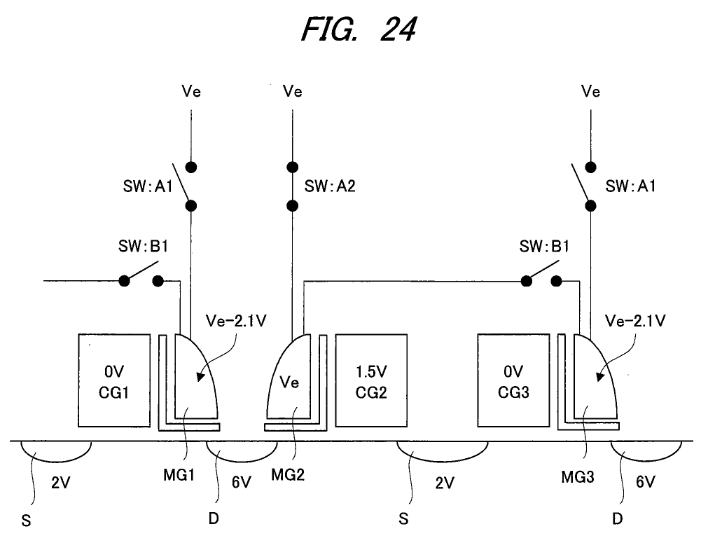

At time t12, the voltage of the selection gate CG (2n+1) is reduced to 0V to reduce the electrode potential of the memory gate MG (2n+1) to (Ve−2.1V) (FIG. 24). Thus, change in potential larger than (capacitive coupling ratio)×(change in the voltage of selection gate) can be obtained.

Similar sequence can be used to repeat the charge sharing and the voltage reduction between the memory gates MG (2n+1) and MG (2n), to further largely reduce the voltage. By this configuration, the size of the charge pump circuit and the chip area can be reduced, producing the effect similar to the first and second embodiments. Compared to the structure described in the first embodiment, the odd-numbered and even-numbered gate electrodes of the switch transistors can be shared. This configuration can further reduce the area occupied by the switch transistor and the chip area, compared to the first embodiment.

Similar to the first embodiment, the third embodiment can preferably be applied to block-by-block erase operation (or mat-by-mat erase operation, a mat comprising a plurality of blocks) where an erase block comprises the memory gates MG1 to MG8, for example.

By applying opposite voltage to the selection gate CG, the electrode potential of the memory gate MG can be boosted. By boosting the electrode potential, the level of the voltage generated in the charge pump circuit at the write operation can be reduced, and the chip area can be reduced, as well.

### Fourth Embodiment

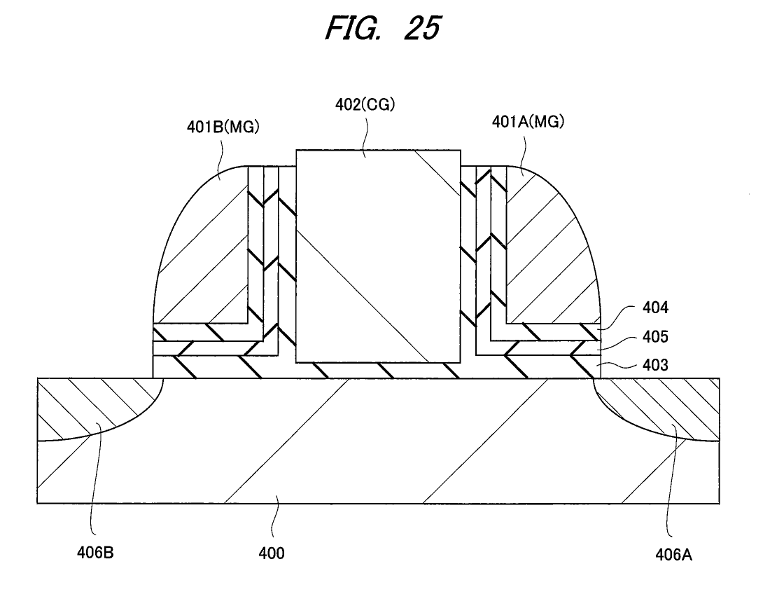

In a fourth embodiment, the memory cell of the non-volatile semiconductor memory device is a so-called twin MONOS comprising memory gates MG arranged on the both sides of the selection gate CG, as shown in FIG. 25. The memory cell comprises diffusion layers 406A and 406B on a silicon substrate 400, and a gate electrode 401A (memory gate MG) and 401B (memory gate MG) that operates the memory and a gate electrode 402 (selection gate CG) that selects a cell, separately. Similar to the first to third embodiments, the memory is operated by injection/discharging charges from a nitride silicon film 405 between the oxide silicon films 403 and 404. In the fourth embodiment, the charge sharing between the two memory gates MG and the voltage reduction using CG is repeated to obtain large reduction in the electrode potential of the memory gate. The fourth embodiment is different from the first to third embodiments in that it uses the memory gate MG to boost (and reduce) the electrode voltage of the electrode of selection gate CG to obtain large change in the potential.

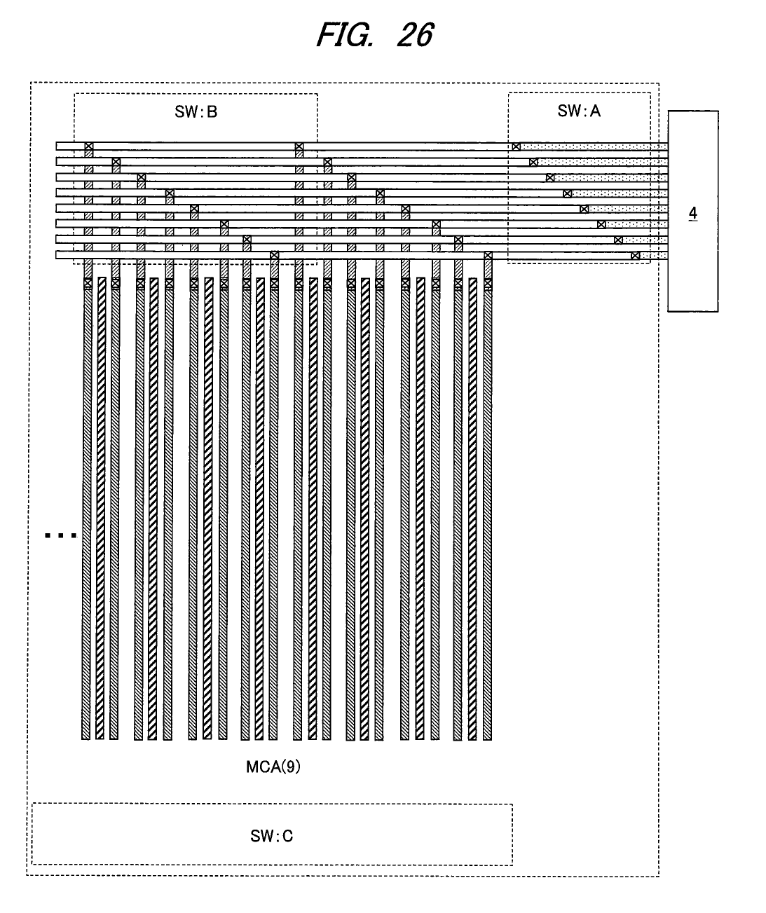

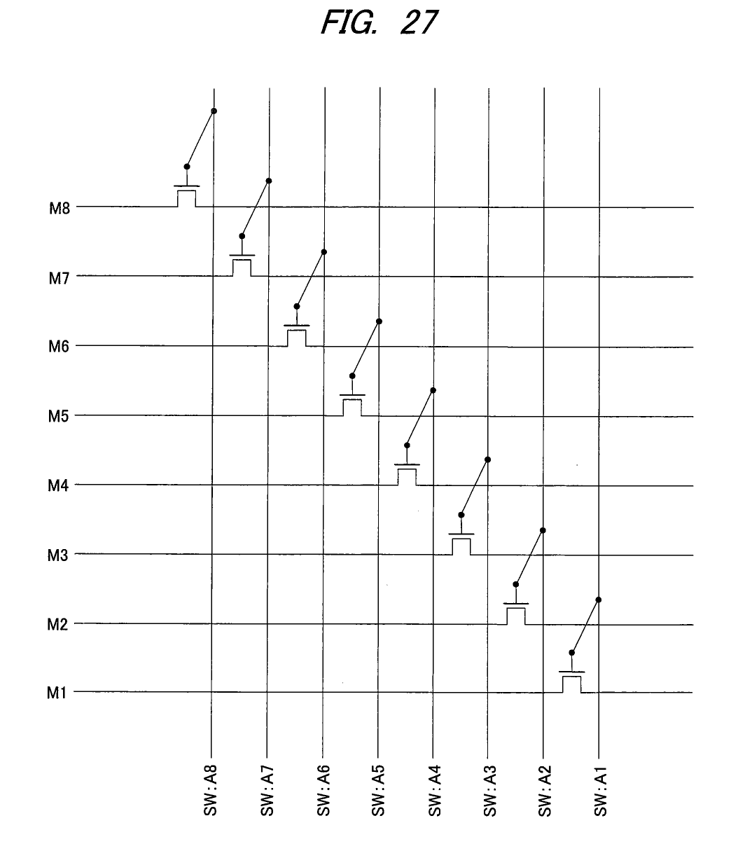

FIG. 26 is a top view showing a part of contact region between two adjacent memory gates in the array structure according to the fourth embodiment. FIGS. 27 to 29 are equivalent circuit diagrams that show a switch transistor A (SW:A) region that turns a memory gate MG into current flowing state/floating state, a switch transistor B (SW:B) region that connects two memory gates MG, and a switch transistor C (SW:C) that turns a selection gate CG into current flowing state/floating state, respectively, in the structure shown in FIG. 26.

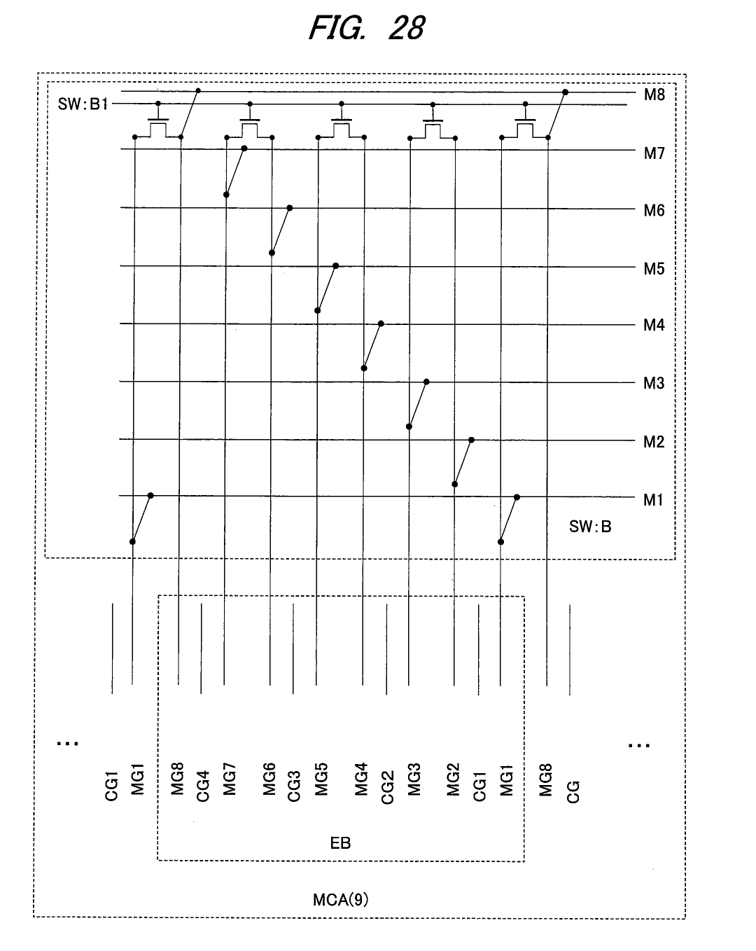

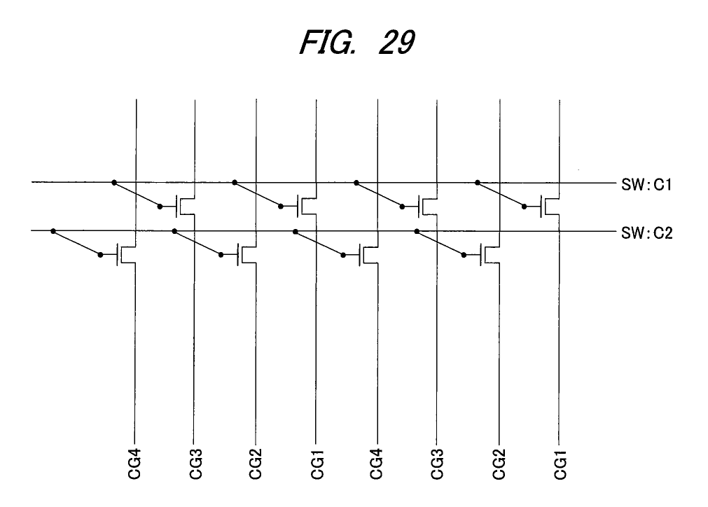

As shown in FIG. 27, the metal wirings M1 to M8 (the metal wirings M1 to M8 are connected to the memory gates MG1 to MG8 (not shown)) can be independently turned into current flowing state/floating state, by the switch transistors A1 (SW:A1) to A8 (SW:A8). As shown in FIG. 28, the switch transistors B1 (SW:B1) connect/disconnect two adjacent memory gates MG, respectively. FIG. 29 shows a switch transistor C (SW:C) region that turns the selection gate CG to current-flowing/floating state. As shown in FIG. 29, the odd-numbered selection gates CG of the eight system of memory gates are connected to the switch transistor C1 (SW:C1) while the even-numbered CG are connected to the switch transistor C2 (SW:C2).

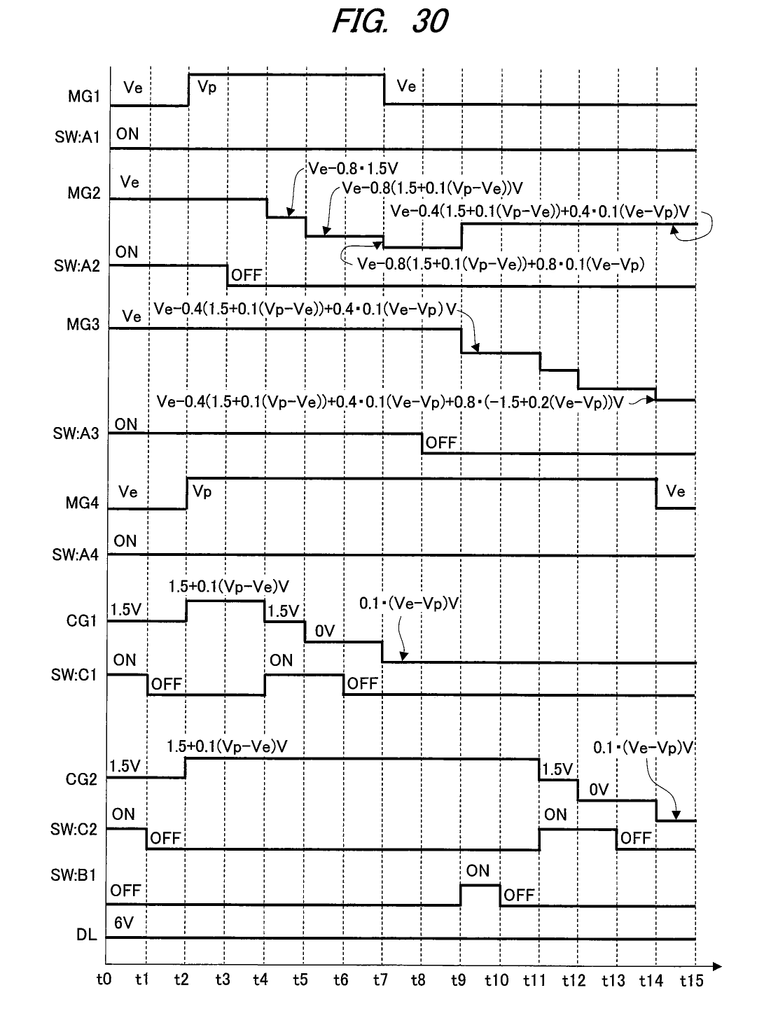

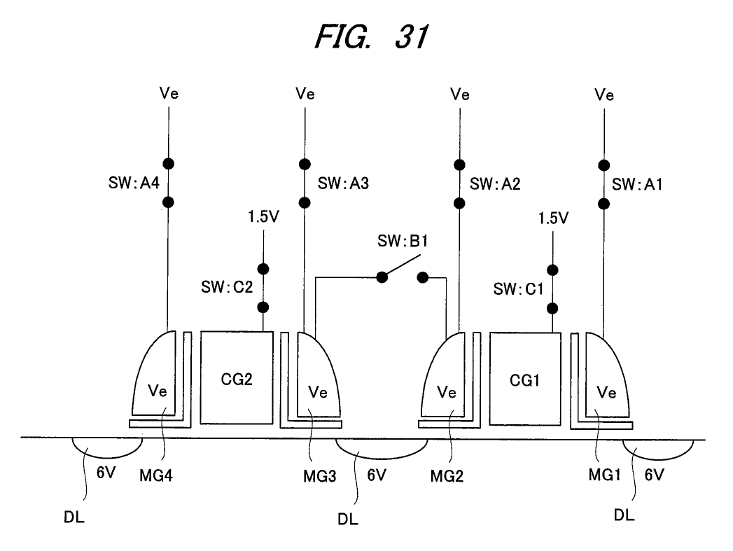

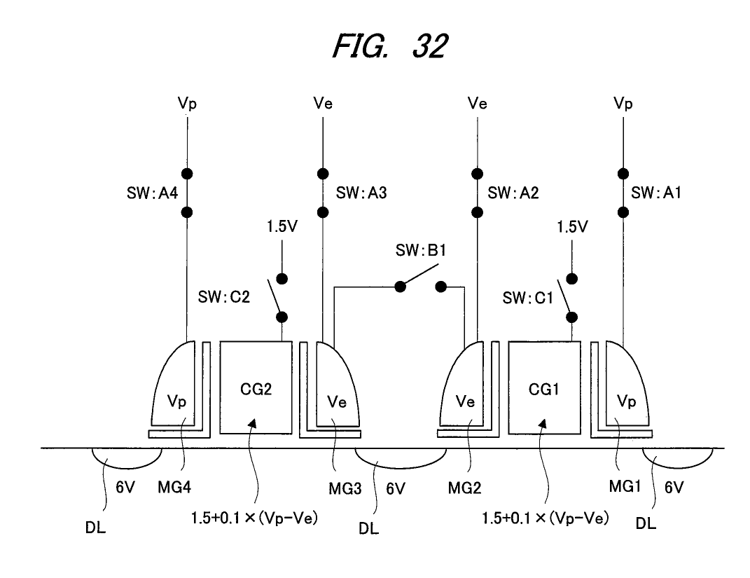

FIG. 30 is a timing chart showing a part of the erase operation of the non-volatile semiconductor memory device according to the fourth embodiment. FIGS. 31 to 36 are figures for describing the erase operation. Here, as an example, it is described that the electrode potential is reduced by the charge sharing between the memory gates MG2 and MG3. DL of FIG. 30 designates a diffusion layer.

At time t0, a voltage of 6V is applied to the diffusion layer DL. The switch transistors A1 (SW:A1) to A4 (SW:A4) that control current flowing state/floating state of the memory gates MG1 to MG4 are in ON state, and a voltage of Ve for the erase operation (for example, −4.8V) is applied to the memory gates MG1 to MG4. The switch transistors C1 (SW:C1) and C2 (SW:C2) are in ON state, and a voltage of 1.5V is applied to the selection gates CG1 and CG2. The switch transistor B1 (SW:B1) is in OFF state (FIG. 31).

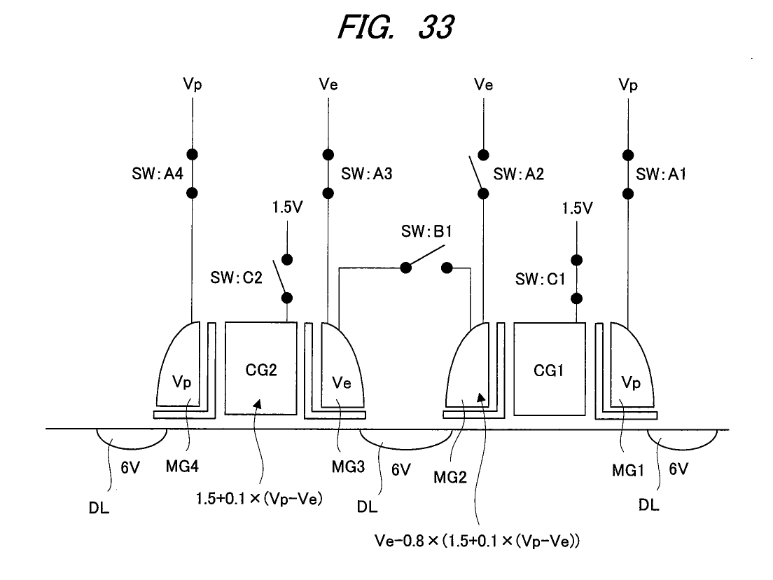

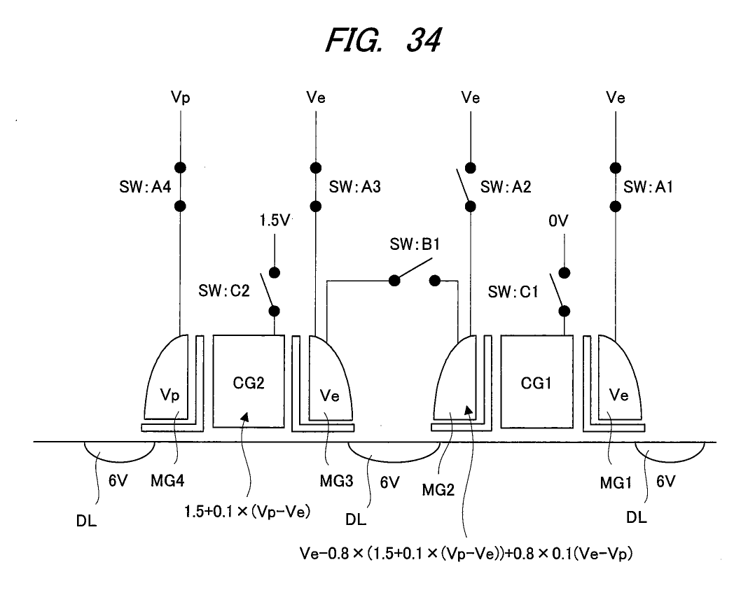

At time t1, the switch transistors C1 (SW:C1) and C2 (SW:C2) are turned into OFF state to turn the selection gates CG1 and CG2 into floating state. At time t2, a voltage Vp (for example, 10V) higher than Ve is applied to the memory gates MG1 and MG4. The electrode potential of the selection gate CG is boosted to (1.5+0.1×(Vp−Ve)) according to the capacitive coupling ratio of the selection gate CG to the memory gate MG (for example, 0.1) and the change in the potential of the memory gates MG1 and MG4. At time t3, the switch transistor A2 (SW:A2) is turned into OFF state to turn the memory gate MG2 into floating state. At time t4, the switch transistor C1 (SW:C1) is turned into ON state to turn the selection gate CG1 into current flowing state (1.5V). At time t5, a voltage of 0V is applied to the selection gate CG1. The voltage of the memory gate MG2 is reduced to (Ve−0.8×(1.5+0.1×(Vp−Ve))) in response to the change in the potential of the selection gate CG1 (FIG. 33). After that, at time t6, the switch transistor C1 (SW:C) is turned into OFF state to turn the selection gate CG1 into floating state. At time t7, a voltage of Ve is applied to the memory gate MG1. The potential of the selection gate CG1 becomes (0.1×(Ve−Vp)) by capacitive coupling. In response thereto, the electrode potential of the memory gate MG2 is reduced to (Ve−0.8×(1.5+0.1×(Vp−Ve))+0.8×0.1×(Ve−Vp) (FIG. 34).

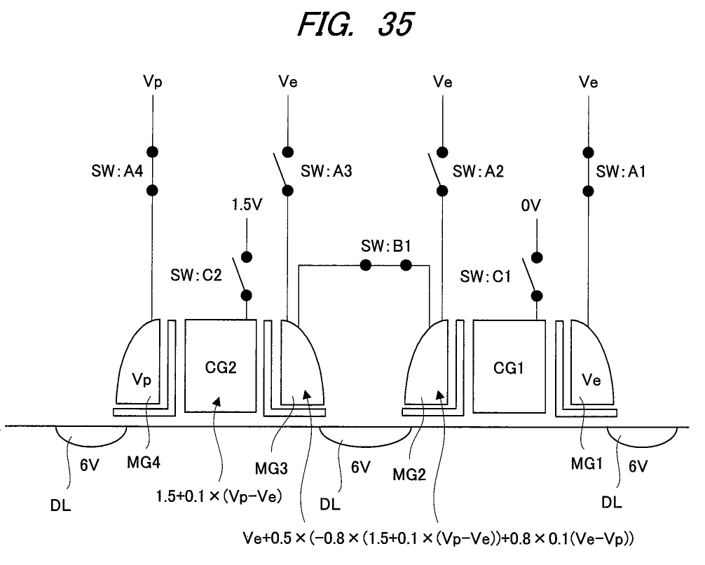

At time t8, the switch transistor A3 (SW:A3) is turned into OFF state to turn the memory gate MG3 into floating state. After that, at time t9, the switch transistor B1 (SW:B1) is turned into ON state to share charges between the memory gates MG2 and MG3. The charge sharing makes the both memory gates MG have equal potential of (Ve+0.5×(−0.8×(1.5+0.1×(Vp−Ve))+0.8×0.1×(Ve−Vp)) (FIG. 35).

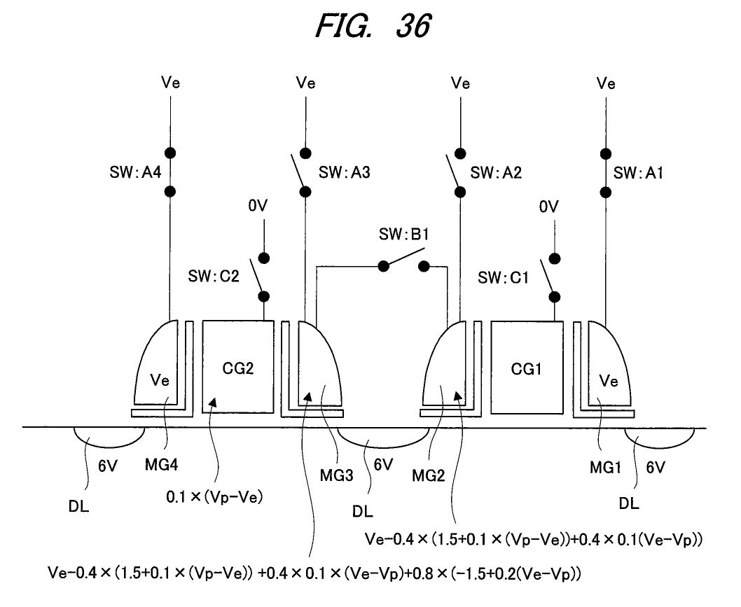

After that, at time t10, the switch transistor B1 (SW:B1) is turned into OFF state to disconnect the memory gates MG2 and MG3. At time t11, the switch transistor C2 (SW:C2) is turned into ON state to flow current through the selection gate CG2 (1.5V). At time t12, a voltage of 0V is applied to the selection gate CG2. At time t13, the switch transistor C2 (SW:C2) is turned into OFF state to turn the selection gate CG2 into floating state. At time t14, a voltage of Ve is applied to the memory gate MG4. Thereby, the potential of the selection gate CG2 becomes (0.1×(Ve−Vp)) by capacitive coupling. In response thereto, the electrode potential of MG3 is reduced to Ve−0.4×(1.5+0.1×(Vp−Ve))+0.4×0.1×(Ve−Vp)+0.8×(−1.5+0.2×(Ve−Vp)) (FIG. 36). Thus, like the first to third embodiments, the fourth embodiment can make it possible to perform the potential change larger than conventional (capacitive coupling ratio)×(change in voltage of selection gate).

Subsequent to the operation at time t14, the charge sharing and the voltage reduction can be repeated between the memory gates MG2 and MG3 in the similar sequences. By this repeated operation, further voltage reduction can be achieved. Like the first to third embodiments, the fourth embodiment can reduce the size of the charge pump circuit as well as the area of the chip.

Similar to the first embodiment, the fourth embodiment can preferably be applied to block-by-block erase operation (or mat-by-mat erase operation, a mat comprising a plurality of blocks) where an erase block comprises memory gates MG1 to MG8, for example.

Alternatively, by changing voltage applied to the selection gate CG from 0V to 1.5V, the electrode potential of the memory gate MG can be boosted. By boosting the electrode potential, the voltage generated in the charge pump circuit at the write operation can be reduced, and the chip area can also be reduced.

### Fifth Embodiment

Although the first to fourth embodiments use capacitive coupling between gates in same memory cell, a fifth embodiment uses capacitive coupling between adjacent word lines (WL) to achieve similar effect. Next, the fifth embodiment will be described in detail.

A non-volatile semiconductor memory device according to the fifth embodiment comprises a so-called NAND flash memory in which charge accumulation nodes of the memory cell are the floating gates (FG: FG1 to FG4), selection gates serving as word lines (WL) are arranged on the floating gates, and the memory cells are serially connected to make an array.

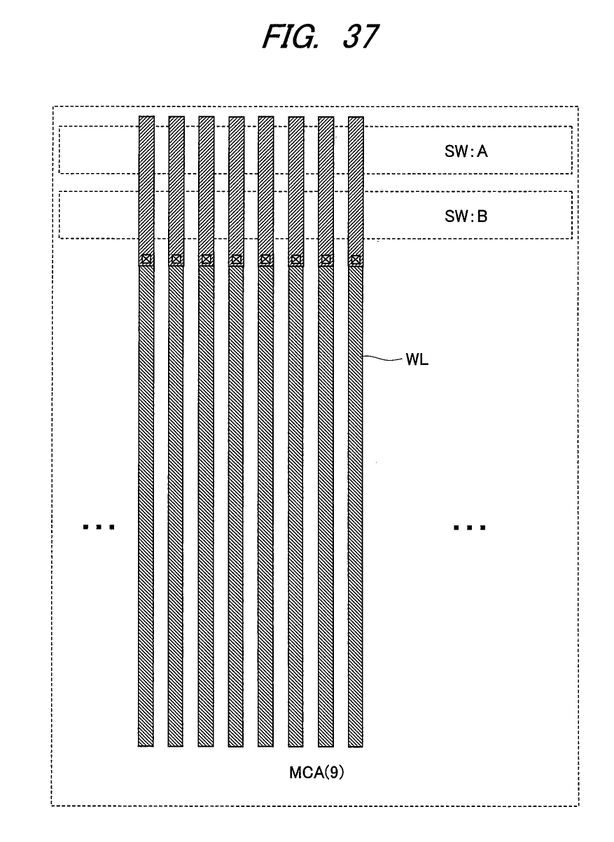

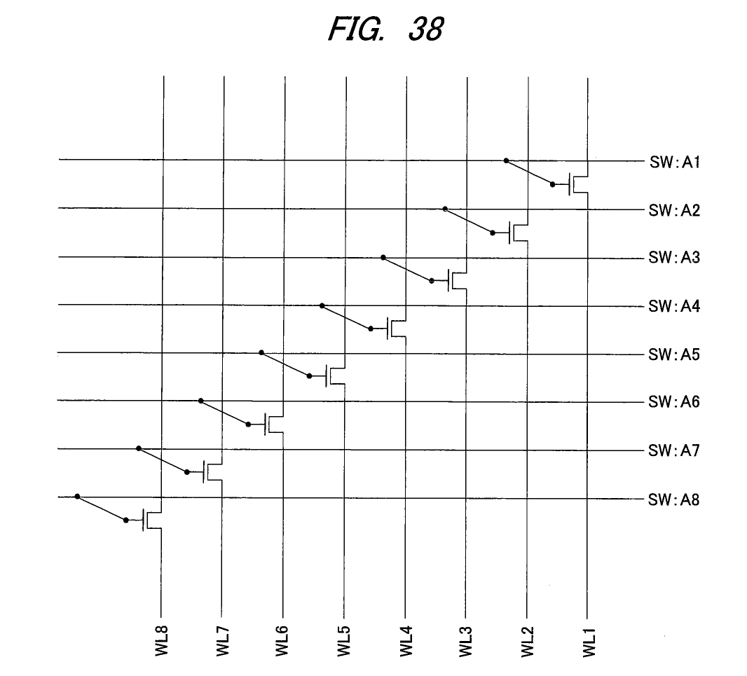

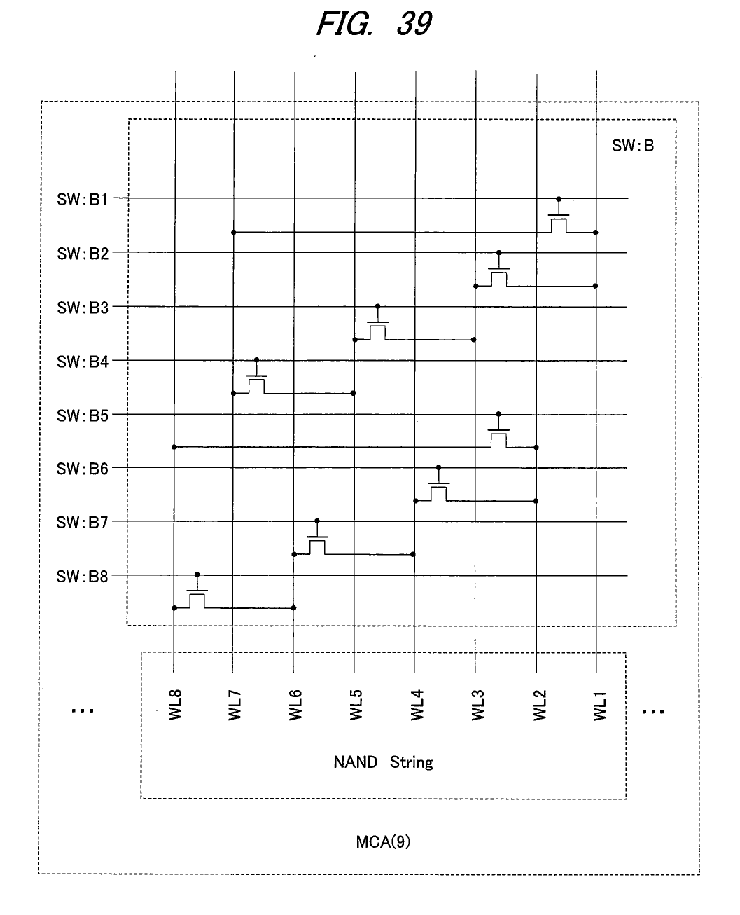

FIG. 37 is a top view showing a part of connection region between adjacent memory gates in the array structure according to the fifth embodiment. FIGS. 38 and 39 are equivalent circuit diagrams showing a switch transistor A (SW:A) region that turns the word line WL into current flowing state/floating state, and a switch transistor B (SW:B) that connects two word lines WL shown in FIG. 37, respectively.

As shown in FIG. 38, the word lines WL1 to WL8 that constitute NAND strings can be independently switched between current flowing state and floating state by the switch transistors A1 (SW:A1) to A8 (SW:A8). As shown in FIG. 39, one in every two word lines WL in the string can be connected/disconnected by the switch transistors B1 (SW:B1) to B8 (SW:B8)

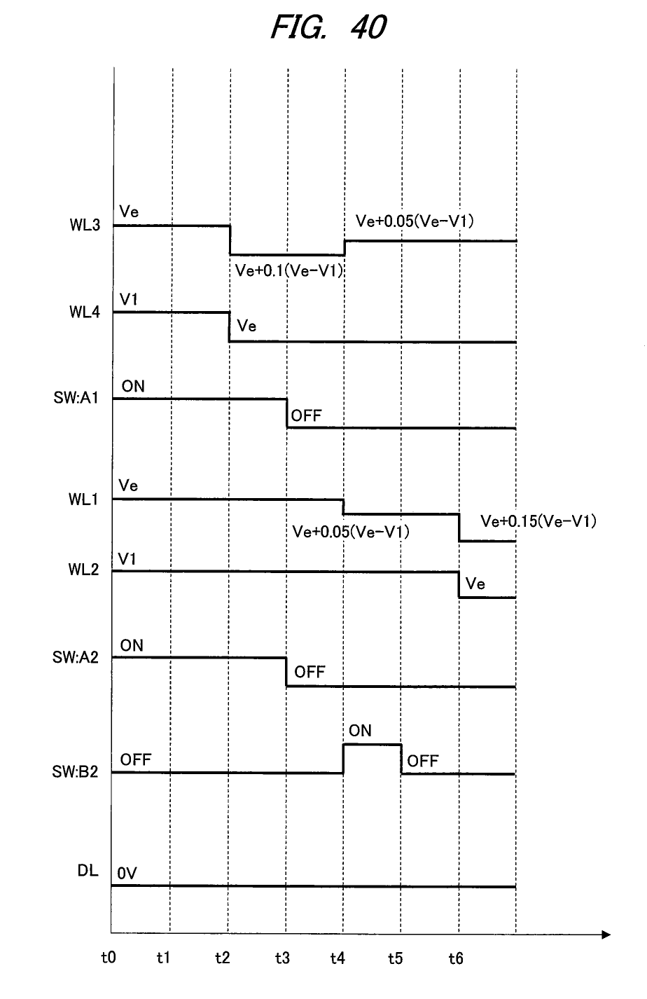

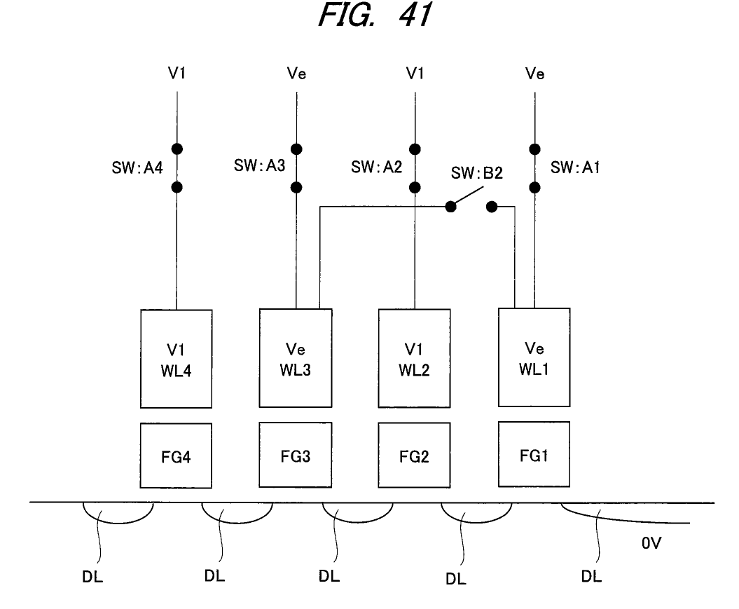

FIG. 40 is a timing chart showing a part of the erase operation of the non-volatile semiconductor memory device according to the fifth embodiment. FIGS. 41 to 45 are figures for describing the erase operation. Here, as an example, reduction in electrode potential of the word line WL1 by the charge sharing between word lines WL1 and WL3 will be described.

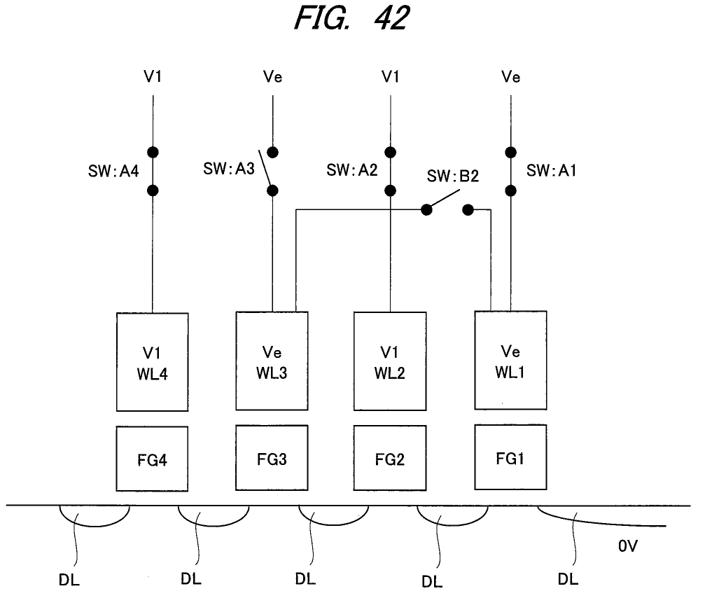

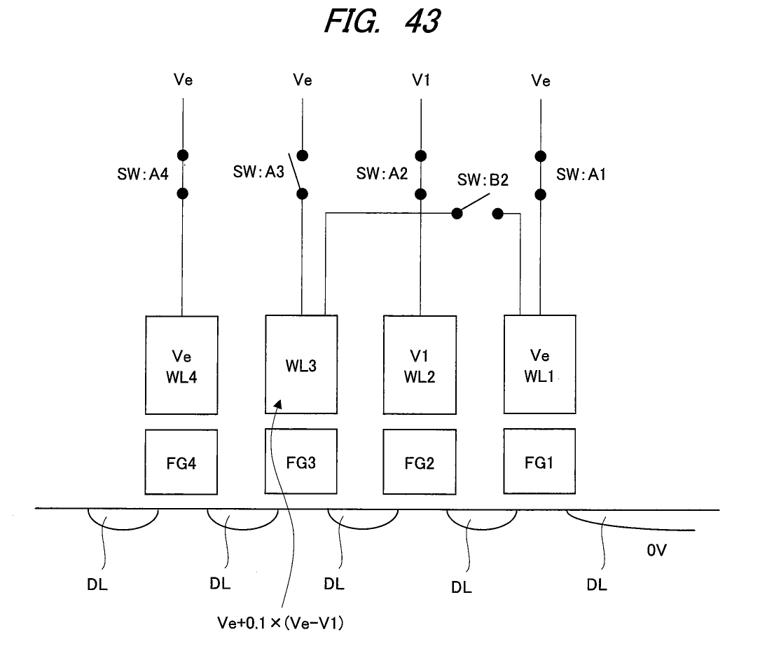

At time t0, a voltage of 0V is applied to the diffusion layer DL. The switch transistors A1 (SW:A1) to A4 (SW:A4) (in FIG. 40, only the switch transistors A1 (SW:A1) and A2 (SW:A2) are shown) are in ON state and the word lines WL1 to WL4 are in current flowing state. And, a negative voltage of Ve near to the erase voltage for NAND is applied to word lines WL1 and WL3, while a positive voltage of V1 which is near to the voltage at which write operation is not performed (lower than write voltage) for the floating gates FG2 and FG4 is applied to word lines WL2 and WL4. The switch transistor B2 (SW:B2) connecting the word lines WL1 and WL3 is in OFF state (FIG. 41). At time t1, the switch transistor A3 (SW:A3) is in OFF state to turn the word line WL3 into floating state (FIG. 42). At time t2, a voltage of Ve is applied to the word line WL4, thereby, the electrode potential of the word line WL3 is reduced according to the capacitive coupling ratio (for example, 0.1) and the change in the potential of the word line WL4 (Ve−V1) (reduced portion: 0.1×(Ve−V1)) (FIG. 43).

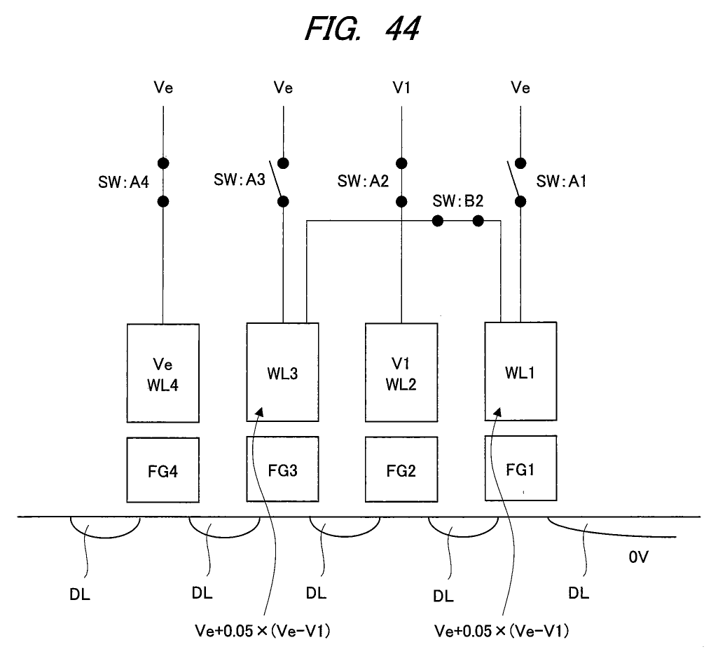

At time t3, the switch transistor A1 (SW:A1) is turned into OFF state to turn the word line WL1 into floating state. At time t4, the switch transistor B2 (SW:B2) connecting word lines WL1 and WL3 is turned into ON state to share the charges accumulated in the word lines WL1 and WL3. At this time, the charge sharing makes the electrode potential between both gates equal, thereby, the electrode potential of the word line WL1 is reduced from the initially applied voltage of Ve to (Ve+0.05×(Ve−V1)), by half (0.05×(Ve−V1)) of the reduced portion at time t2 (FIG. 44).

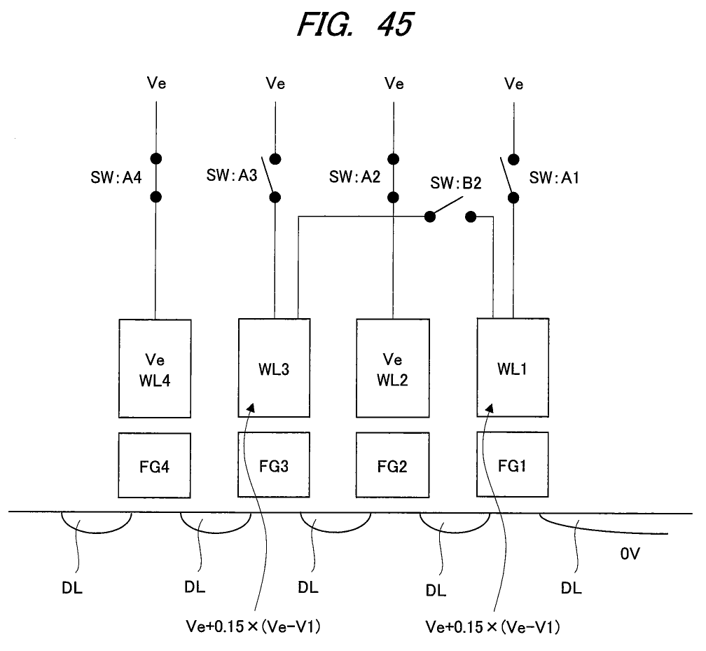

Next, at time t5, the switch transistor B2 (SW:B2) is turned into OFF state to disconnect the word lines WL1 and WL3. At time t6, a voltage of Ve is applied to the word line WL2. Thereby, the electrode potential of the word line WL1 is reduced to (Ve+0.15×(Ve−V1)) according to capacitive coupling ratio and the change in the voltage of the word line WL2 (FIG. 45). Thus, the potential change larger than (capacitive coupling ratio)×(voltage change in the word line) can be obtained.

In the memory cell array according to the fifth embodiment, the memory gates are controlled in eight systems. Therefore, subsequent to the operation shown in FIG. 40, the charge sharing and the voltage reduction can be repeated for the word lines WL7, WL5, WL3 and WL1 in the similar sequence. By this repeated operation, the voltage reduction can be achieved further largely.

Similar to the first embodiment, the fifth embodiment can preferably be applied to block-by-block erase operation (or mat-by-mat erase operation, a mat comprising a plurality of blocks).

In the fifth embodiment, a string comprises eight memory cells. However, same effect can be obtained for a string having more than eight memory cells, by increasing the number of switch transistors, accordingly.

By applying opposite voltage to the adjacent word lines, the electrode potential of the memory gate can be boosted. In further aspect of the invention, by applying inhibit voltage to the diffusion layer, the write operation can be allowed or inhibited. Higher electrode potential can reduce the voltage level generated by the charge pump circuit at the write operation, which, in turn, can reduce the area of the chip.

### Sixth Embodiment

The array of the non-volatile semiconductor memory device according to a sixth embodiment is similar to that according to the fifth embodiment except the structure of the memory cell. The memory cell of the sixth embodiment comprises a tunnel film made from an oxide silicon film or the like, a charge accumulation film made from a nitride silicon film, a block film made from alumina or the like, and a gate electrode made from tantalum nitride or the like are formed on a silicon substrate.

In a floating gate type memory cell, the sequence quite similar to that in the fifth embodiment can be used to boost or reduce the potential of the selection gate, and to reduce the voltage generated by the charge pump circuit for write or erase operation.

As a result, the size of a charge pump circuit and the chip area can be reduced.

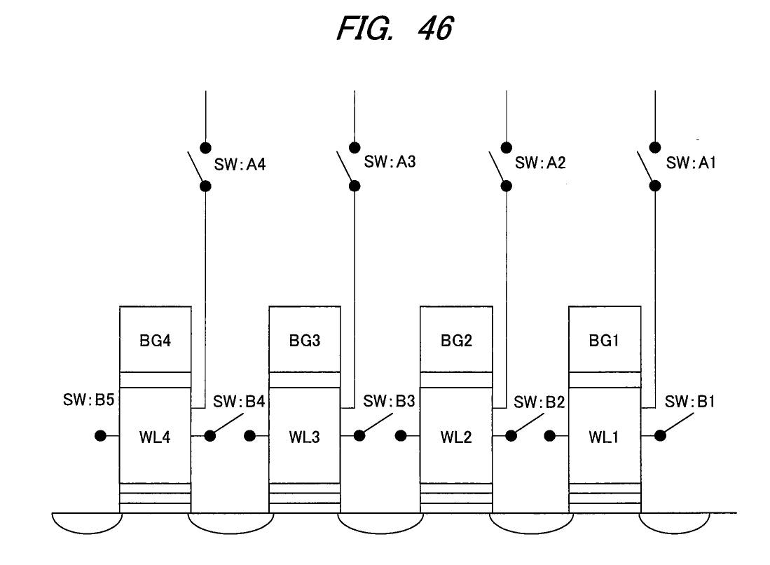

As shown in FIG. 46, this embodiment is applicable to a memory cell in which boost electrodes BG (BG1 to BG4) are disposed on the selection gates (word lines WL (WL1 to WL4)) of a single gate memory cell.

This invention can be applied not only to the memory cells described in the first to sixth embodiments, but also to any non-volatile semiconductor memory device provided that the device generates a voltage higher than supply voltage in the chip. The invention is not limited to the above described embodiments. Various modifications can be made without departing from the spirit of the invention. For example, in the embodiments 1 to 4, a dielectric trap-type memory cell having a nitride silicon film as a charge accumulation film is used for description. However, the charge accumulation film is not limited to a nitride silicon film, a dielectric that can accumulate charges can also be employed. Furthermore, instead of a dielectric, a conductive film such as silicon can also be employed to achieve same effect. On the contrary, the fifth embodiment uses a floating gate type memory cell that uses a conductive film such as a silicon film is used as a charge accumulation film. However, same effect can be obtained in a dielectric trap-type memory cell that uses a dielectric.

### Seventh Embodiment

### Charge Sharing between Selection Memory Block and Non-Selection Memory Block

The structure of a seventh embodiment is different from that of the third embodiment in that, in the seventh embodiment, the memory gate voltage is reduced in a non-selection memory block in a memory cell array, then the charge sharing is carried out between the memory gates of the selection memory block and the non-selection memory block. In other words, in the third embodiment as described above, the charge sharing is carried out between a plurality of memory gates in one selection memory block. However, in the seventh embodiment, the charge sharing is carried out between a memory gate electrode in a non-selection memory block and that in a selection memory block.

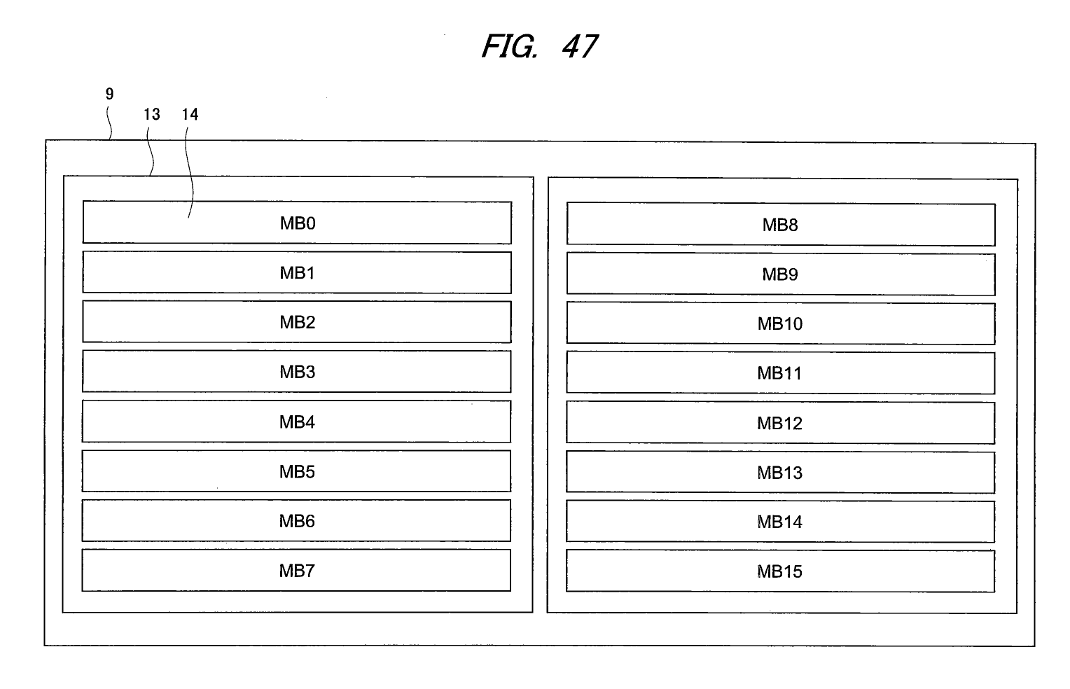

FIG. 47 is a diagram showing a precise exemplary structure of a memory cell array 9 in FIG. 1. As shown in FIG. 47, the memory cell array 9 comprises two memory mats 13, and one memory mat 13 comprises eight memory blocks 14. For example, the memory mat 13 on the left side of the memory cell array 9 comprises the memory blocks 14 (MB0 to MB7), and the memory mat 13 on the right side of the memory cell array 9 comprises the memory blocks 14 (MB8 to MB15).

As shown in FIG. 13, each memory block 14 comprises a plurality of metal wirings M1 to M8, and switch transistors SW:A that control connect/disconnect (floating) of the metal wirings M1 to M8 are provided. As shown in FIG. 14, each memory block 14 comprises memory gate electrodes MG1 to MG8 respectively connected to the metal wirings M1 to M8. MG1 to MG8 adjacent to each other are connected/disconnected by the switch transistor SW:B.

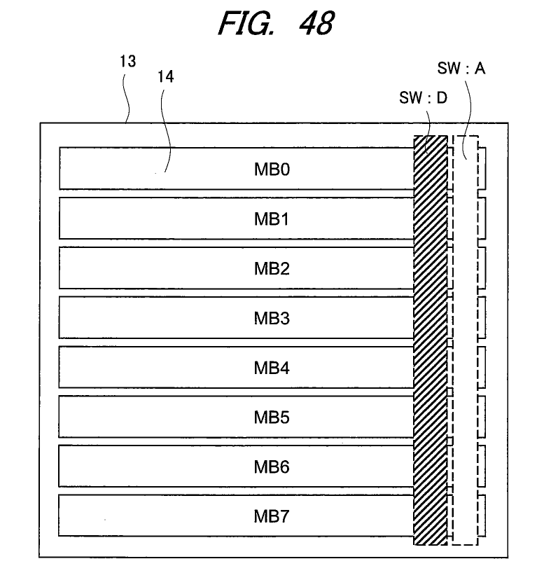

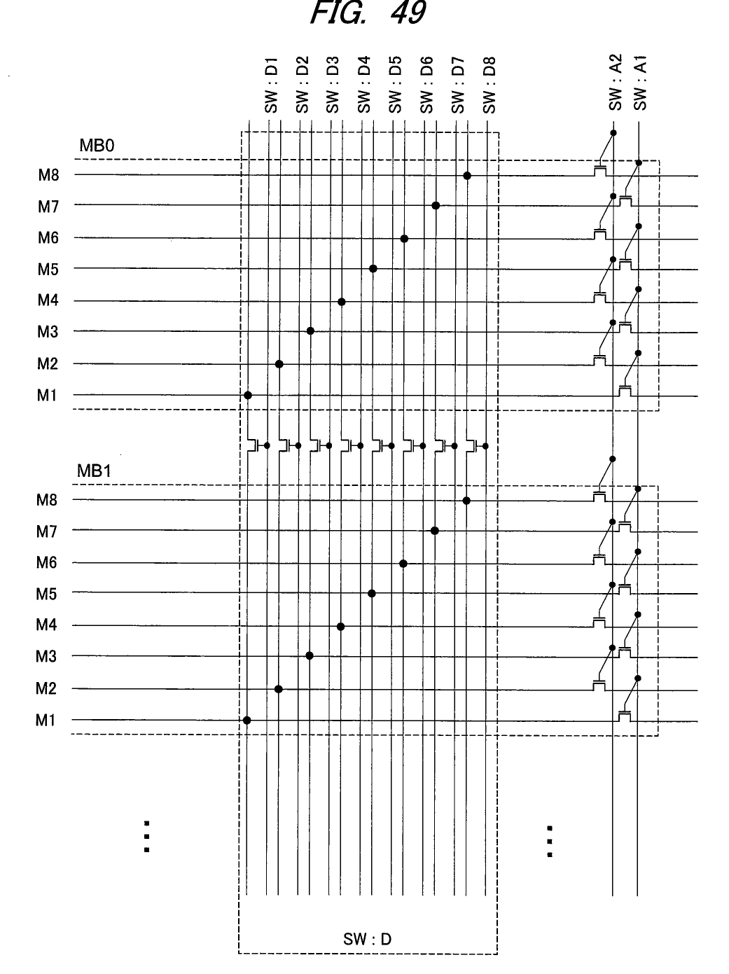

Next, as shown in FIG. 48, one memory mat 13 has eight memory blocks 14 (MB0 to MB7), which, in turn, are connected by a switch transistor SW:D. FIG. 48 schematically shows a switch transistor SW:D that connects the memory blocks 14 (MB0 to MB7) in a memory mat 13 shown in FIG. 47. FIG. 49 shows an equivalent circuit diagram of a switch transistor SW:D that connects a plurality of memory blocks (in FIG. 49, memory block 14 (MB0 and MB1)). As shown in FIG. 49, a switch transistor SW:D comprises eight switch transistors SW:D (SW:D1 to D8) system. For example, the switch transistor SW:D1 connects the metal wirings M1 to each other in each of the memory blocks (MB0 to MB7). As shown in FIG. 49, the switch transistors SW:A (SW:A1, SW:A2) are connected by two systems in the memory block 14 (MB0 to MB7). Although not illustrated in FIG. 49, each of the memory blocks 14 (MB0 to MB7) is also provided with a switch transistor SW:B, respectively.

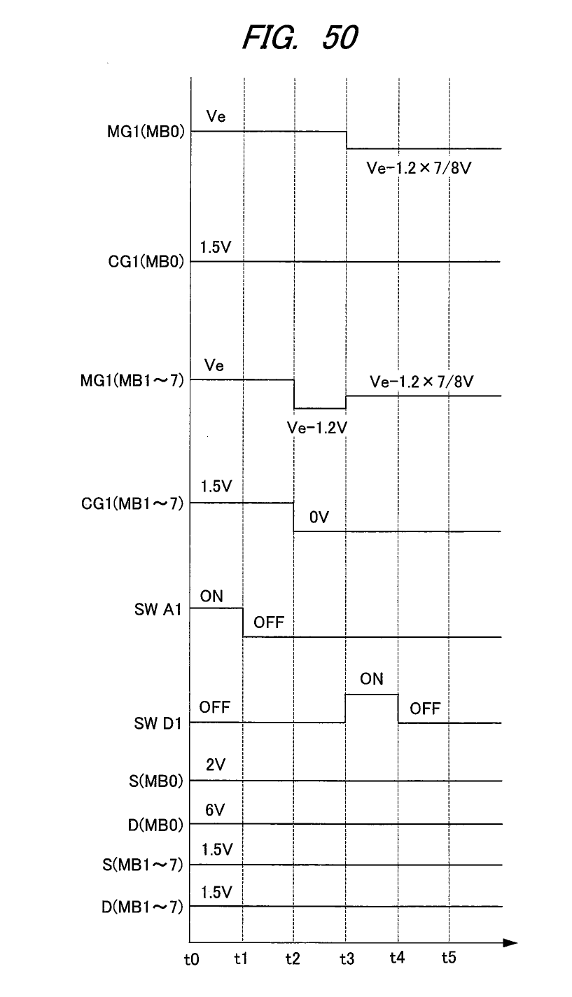

Next, operation of the charge sharing between a plurality of memory blocks arranged as above will be described. FIG. 50 is a timing chart showing a part of the erase operation of the non-volatile semiconductor memory device according to the seventh embodiment. Since some steps are same as that explained in the third embodiment with reference to FIG. 15, regarding to FIG. 50, the reduction of a memory gate potential in the non-selection memory blocks (MB1 to MB7) and the charge sharing between a selection memory block (MB0) and a non-selection memory block (MB1 to MB7) will be described. The flow chart shown in FIG. 50 shows an example in which the potential of the memory gate electrode MG1 connected to the metal wiring M1 of FIG. 49 is reduced.

At time to, the switch transistor SW:A1 is in ON state, and a voltage of Ve is applied to the memory gate electrodes (MG1) of eight memory blocks 14 (MB0 to MB7) from the control circuit via the switch transistor SW:A1. That is, a voltage of Ve is applied to the memory gate electrode (MG1) of one selection memory block (MB0), and to the memory gate electrodes (MG1) of other seven non-selection memory blocks (MB1 to MB7). Also at time t0, a voltage of 1.5V is applied to the control gate electrode (CG1) of the selection memory block (MB0), and those (CG1) of the non-selection memory blocks (MB1 to MB7). Voltages of 2V and 6V are applied to the source S and the drain D of the selection memory block (MB0), respectively, and a voltage for the erase operation is applied to the source S and the drain D of a selection memory block (MB0). On the other hand, a voltage of 1.5V is applied to the source S and the drain D of the non-selection memory blocks (MB1 to MB7). The switch transistor SW:D1 that connects the metal wirings M1 arranged in each of the memory blocks 14 (MB0 to MB7) is in OFF state.

Subsequently, at time t1, the switch transistor SW:A1 is turned into OFF state by the control circuit to turn the memory gate electrode (MG1) of the selection memory block (MB0) and those (MG1) of the non-selection memory blocks (MB1 to MB7) into floating state.

At time t2, the voltage of the control gate electrodes (CG1) of the non-selection memory blocks (MB1 to MB7) is reduced from 1.5V to 0V by the control circuit. The potential of the memory gate electrodes (MG1) in the non-selection memory blocks (MB1 to MB7) is reduced according to the capacitive coupling ratio (0.8) and change in the voltage of the control gate electrodes (CG1) (reduced portion: 0.8×1.5=1.2V). That is, the potential of the memory gate electrodes (MG1) arranged in the non-selection memory blocks (MB1 to MB7) becomes Ve−1.2V.

At time t3, the switch transistor SW:D1 is turned into ON state by the control circuit. Thereby, the memory gate electrode (MG1) of the selection memory block (MB0) and those (MG1) of the non-selection memory blocks (MB1 to MB7) are electrically connected. Thus, the charges accumulated in the memory gate electrodes (MG1) of the non-selection memory blocks (MB1 to MB7) are supplied to those of the selection memory block (MB0) to perform charge sharing. At this time, the charge sharing makes the potential of the memory gate electrodes (MG1) of the non-selection memory blocks (MB1 to MB7) and that of the memory gate electrode (MG1) of the selection memory block (MG0) equal (same potential). Therefore, the voltage of the memory gate electrode (MG1) of the selection memory block (MB0) is reduced (Ve−1.2×⅞ V) from the initially applied voltage of Ve by ⅞ of the reduction (1.2 V×⅞) in the non-selection memory blocks (MB1 to MB7) at time t2.

After that, at time t4, the switch transistor SW:D1 is turned into OFF state by the control circuit, to electrically disconnect the memory gate electrode (MG1) of the selection memory block (MB0) and those (MG1) of the non-selection memory blocks (MB1 to MB7). Thus, the voltage applied to the memory electrodes (MG1) in the non-selection memory blocks (MB1 to MB7) is reduced, then the charge sharing is carried out between the memory electrode (MG1) of the selection memory block (MB0) and those (MG1) of the non-selection memory blocks (ME1 to MB7), in the memory cell array 9. As a result, the voltage of the memory gate electrode (MG1) of the selection memory block (MB0) can be reduced.

Subsequently, for example, as described in the third embodiment, the charge sharing is carried out between the memory gate electrodes (MG1 to MG8) in the selection memory block (MB0), to perform the erase operation in the memory gate electrode (MG1) in the selection memory block (MB0). Thus, the seventh embodiment is characterized in that the erase operation is carried out after the charge sharing is performed in two steps. That is, as explained with reference to FIG. 50, the charge sharing is carried out between the memory gate electrode (MG1) of the selection memory block (MB0) and those (MG1) of the non-selection memory electrodes (MB1 to MB7) to reduce the voltage of the memory gate electrode (MG1) of the selection memory block (MB0). Then, as described in the third embodiment with reference to FIG. 15, the charge sharing is carried out between the memory gate electrodes (MG1 to MG8) arranged in the selection memory block (MB0). In this case, in the charge sharing shown in FIG. 15, the initial potential at time t0 shown in FIG. 15 is not Ve. Instead, voltage is reduced from Ve−1.2×⅞V that is reduced from Ve.

Compared to the third embodiment, above described sequence for the erase operation can further reduce the potential of the memory gate voltage (MG1). Therefore, the memory gate electrode (MG1) can have high potential even when lower voltage is generated by the charge pump circuit for negative voltage supply. As a result, the size of the charge pump circuit and the area of chip can be reduced. In other words, since the potential of the memory gate electrode (MG1) in the selection memory block (MB0) is sufficiently reduced by the charge sharing in two steps, fewer loads are imposed on the charge pump circuit to reduce the voltage of the memory gate electrode (MG1) in the selection memory block (MB0) to erase voltage. Since the load imposed on the charge pump circuit becomes small, it is possible to make the size of the charge pump circuit and the chip area smaller.

In the seventh embodiment, the charge sharing is carried out between the memory gate electrode (MG1) of the selection memory block (MB0) and those (MG1) of the non-selection memory blocks (MB1 to MB7) to reduce the voltage of the memory gate electrode (MG1) of the selection memory block (MB0). Then, the charge sharing is carried out between the memory gate electrodes (MG1 to MG8) in the selection memory block (MB0), as explained in the third embodiment with reference to FIG. 15. However, when the memory gate electrode (MG1) of the selection memory block (MB0) can sufficiently be reduced by the charge sharing between the memory gate electrode (MG1) of the selection memory blocks (MB0) and those (MG1) of the non-selection memory block (MB1 to MB7), the charge sharing between the memory gate electrodes (MG1 to MG8) arranged in the selection memory block (MB0), as described in the third embodiment with reference to FIG. 15, is not necessary.

In the seventh embodiment, two steps of the charge sharing are carried out for the memory gate electrode (MG1) in the selection memory block (MB0). But, the sequence of the erase operation is not limited to this sequence. For example, the charge sharing can be carried out between the memory gate electrode (MG1) in the selection memory block (MB0) and those (MG1) in the non-selection memory block (MB1 to MB7), then between the memory gate electrodes (MG2 to MG8) in the selection memory block (MB0) and the memory gate electrodes (MG2 to MG8) in the non-selection memory block (MB1 to MB7), respectively. Furthermore, the charge sharing can be carried out between the memory gate electrodes (MG1 to MG8) in the selection memory block (MB0) and those in the non-selection memory blocks (MB1 to MB7) respectively at the same time. This configuration can reduce the time necessary for the erase operation.

In the seventh embodiment, the voltage reduction in the memory gate electrode for the erase operation is described. In further aspect of the present invention, for example, the charge sharing can be applied for voltage boost of the memory gate electrode for the write operation.

The structure of the switch transistor SW:B in the memory block according to the seventh embodiment is similar to that according to the third embodiment. However, same effect can be obtained obviously when the structure or operation according to the first or second embodiment is used.

### Eighth Embodiment

### Charge Sharing between Selection Memory Mat and Non-Selection Memory Mat→Charge Sharing between Selection Memory Block and Non-Selection Memory Block

In the seventh embodiment, the voltage reduction and the charge sharing are carried out between the selection memory block and the non selection memory block in a memory mat to reduce the voltage necessary for the erase operation. In a eighth embodiment, the voltage reduction and the charge sharing are additionally carried out between different memory mats, thereby, the erase operation can be carried out with further reduced potential of the memory gate electrode.

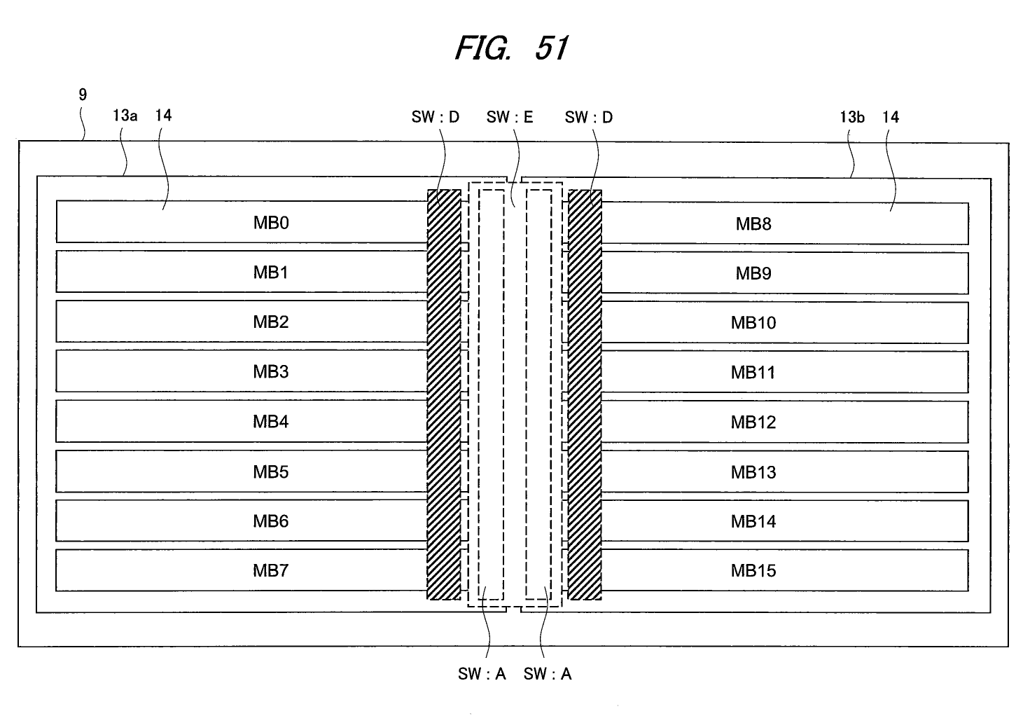

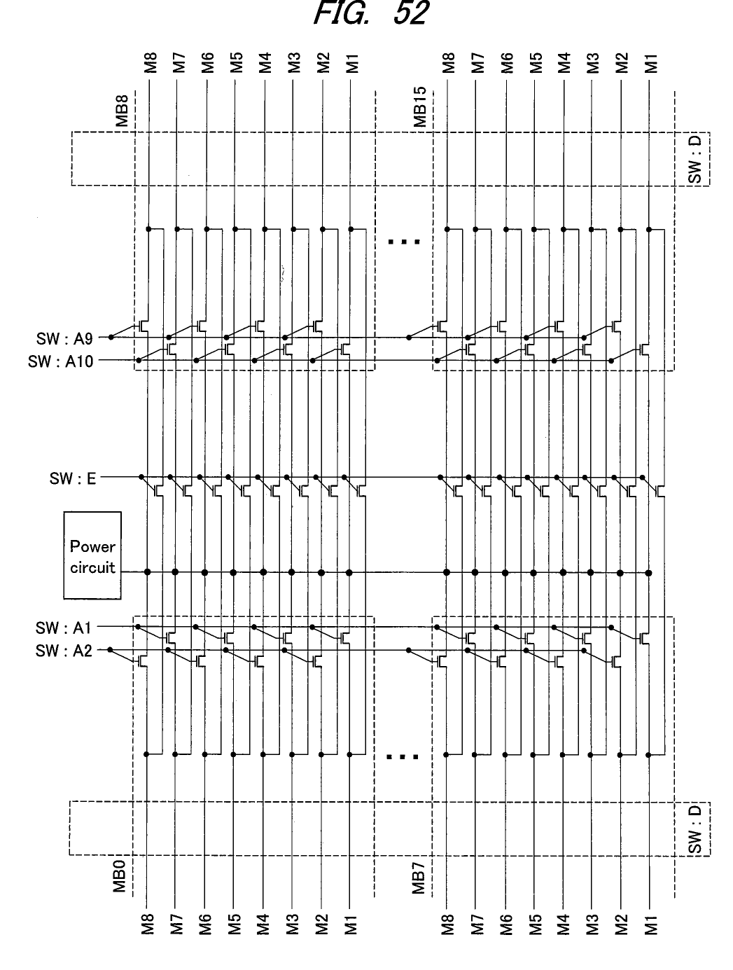

The structure of the memory cell array 9 according to the eighth embodiment is similar to that shown in FIG. 47. FIG. 51 shows the structure of the memory cell array 9 and that of the switch transistors according to the eighth embodiment, and FIG. 52 shows their equivalent circuits. As shown in FIG. 51, the memory cell array 9 comprises two memory mats 13a and 13b, which, in turn comprise eight memory blocks 14. For example, in the memory mat 13a on the left side of the memory cell array 9, memory blocks 14 (MB0 to MB7) are formed, while in the memory mat 13b on the right side of the memory cell array 9, memory blocks 14 (MB8 to MB15) are formed.

As shown in FIG. 13, in the memory blocks 14, a plurality of metal wirings M1 to M8 are arranged, and switch transistors SW:A which control connect/disconnect (floating) of the metal wirings M1 to M8 are provided. In each of the memory blocks 14, a plurality of metal wirings M1 to M8 and a plurality of memory gate electrodes MG1 to MG8 respectively connected thereto are arranged. The memory gate electrodes MG1 to MG8 adjacent to each other are connected/disconnected by the switch transistors SW:B.

As shown in FIG. 51, the memory mats 13a and 13b have eight memory blocks 14 (MB0 to MB7, MB8 to MB15) respectively. These eight memory blocks 14 (MB0 to MB7, MB8 to MB15) in each of the memory mats 13a and 13b are connected by a switch transistor SW:D. In the eighth embodiment, two different memory mats are connected to each other by a switch transistor SW:E. As shown in FIG. 52, the switch transistor SW:E is one system. For example, the metal wirings (M1 to M8) of the memory block (MB0) in the memory mat 13a and those (M1 to M8) of the memory blocks (MB0 to MB15) of its counterparts in the memory mat 13b are respectively connected via the switch transistor SW:E.

As shown in FIG. 52, the switch transistors SW:A (SW:A1, SW:A2, SW:A9, SW:A10) are connected in two systems over the memory blocks 14 (MB0 to MB15). Not shown in FIG. 52, switch transistor SW:B is respectively provided in each of the memory blocks 14 (MB0 to MB15).

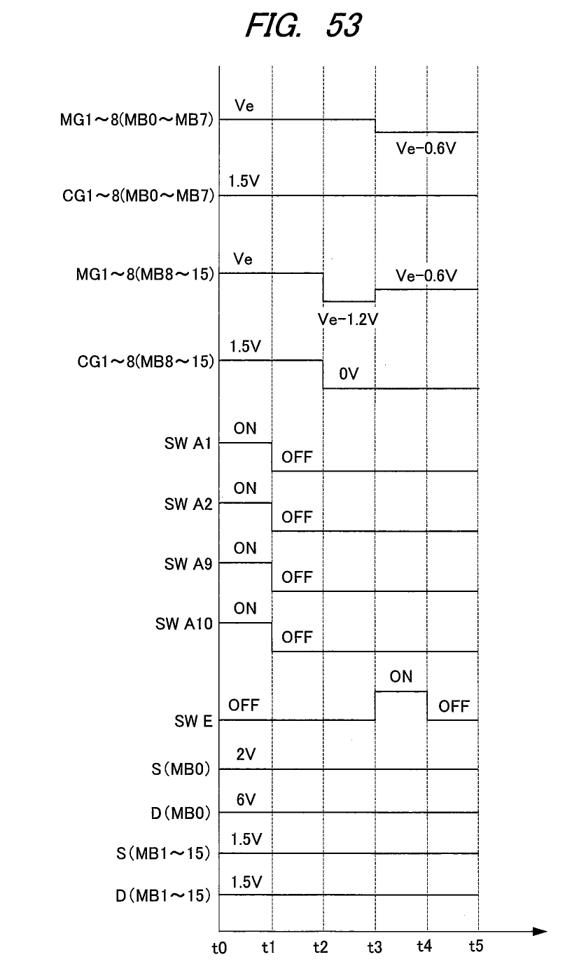

Next, the charge sharing operation between two different memory mats having above structure will be described. FIG. 53 is a timing chart showing a part of the erase operation of the non-volatile semiconductor memory device according to the eighth embodiment. Some steps in the erase operation according to the eighth embodiment are similar to those explained with reference to FIGS. 50 and 15. Thus, regarding to FIG. 53, the reduction of potential applied to the memory gate electrodes of the non-selection memory mats (MB8 to MB15) and the charge sharing operation between the selection memory mats (MB0 to MB7) and the non-selection memory mats (MB8 to MB15) will be described.

First, at time t0, the switch transistors SW:A1 to A2 and A9 to A10 are in ON state, and a voltage of Ve is applied to the memory gate electrodes (MG1 to MG8) of the memory blocks (MB0 to MB15) via the power supply circuit and the metal wirings M1 to M8. At this time, the switch transistor SW:E is in OFF state. A voltage of 1.5V is applied to all control gate electrodes (CG1 to CG8) including those (CG1 to CG8) in the non-selection memory mat (memory blocks MB8 to MB15), and those (CG1 to CG8) in the selection memory mat (memory blocks MB0 to MB7). A voltage of 1.5V is applied to the source S and the drain D of the memory blocks (MB0 to MB15) other than the selection memory block (MBC) included in the selection memory mat (memory mat 13a). A voltage of 2V is applied to the source S, and a voltage of 6V is applied to the drain D, of the selection memory block (MB0) included in the selection memory mat (memory mat 13a).

At time t1, the switch transistors SW:A1 to SW:A2 and SW:A9 to SW:A10 are turned into OFF state to turn all memory gate electrodes (MG1 to MG8) included in the selection memory mat (memory mat 13a) and the non-selection memory mat (memory mat 13b) into floating state.

At time t2, the potential of all control gate electrodes (CG1 to CG8) included in the non-selection memory mat (MB8 to MB15) is reduced from 1.5V to 0V. Thereby, the voltage of all memory gate electrodes (MG1 to MG8) in the non-selection memory mat (MB8 to MB15) is reduced to (Ve−1.2V) by capacitive coupling.

At time t3, the switch transistor SW:E is turned into ON state, and the charge sharing is carried out between the memory gates electrodes (MG1 to MG8) in the memory mat 13a and their counterparts (MG1 to MG8) in the memory mat 13b. Thereby, the potential of all memory gate electrodes (MG1 to MG8) of the selection memory mat (MB0 to MB7) including the selection block is reduced to (Ve−0.6V).

At time t4, the switch transistor SW:E is turned into OFF state. Thus, the voltage applied to the memory gate electrode (MG1 to MG8) in the non-selection memory mat (MB8 to MB15) is reduced, then the charge sharing is carried out between the memory gate electrodes (MG1 to MG8) in the non-selection memory mat (MB8 to MB15) and their counterparts (MG1 to MG8) in the selection memory mat (MB0 to MB7), in the memory cell array 9. Thus, the voltage of the memory gate electrode (MG1 to MG8) in the selection memory mat (MB0 to MB7) can be reduced.

Subsequently, for example, as described in the seventh embodiment, the voltage reduction and the charge sharing are carried out between the selection memory block (MB0) and the non-selection memory blocks (MB1 to MB7) in the same memory mat (MB0 to MB7). Then, as described in the third embodiment, the charge sharing is carried out between the memory gate electrodes (MG1 to MG8) in the selection memory block (MB0). Thereafter, the erase operation is carried out for the memory gate electrode (MG1) in the selection memory block (MB0). The eighth embodiment is characterized in that the erase operation is carried out after three steps of the voltage reduction and the charge sharing are performed.

By the erase operation using the sequence as above, the potential of the memory gate electrode (MG1) can further be reduced compared to the third and seventh embodiments. The memory gate electrode (MG1) can have high potential even when lower voltage is generated by the charge pump circuit for negative voltage supply. As a result, the size of the charge pump circuit and the area of chip can be reduced. In other words, the potential of the memory gate electrode (MG1) in the selection memory block (MB0) is sufficiently reduced by the voltage reduction and the charge sharing in three steps. Thus, it is possible to decrease loads which are imposed on the charge pump circuit to reduce the voltage of the memory gate electrode (MG1) in the selection memory block (MB0) to erase voltage. Because the loads imposed on the charge pump circuit are decreased, it is possible to make the size of the charge pump circuit small and to reduce the area of chip.

In the eighth embodiment, the voltage applied to the memory gate electrodes (MG1 to MG8) in the non-selection memory mat (MB8 to MB15) is reduced, then the charge sharing is carried out between the memory gate electrodes (MG1 to MG8) in the non-selection memory mat (MG8 to MB15) and their counterparts (MG1 to MG8) in the selection memory mat (MB0 to MB7) to reduce the voltage of the memory gate electrodes (MG1 to MG8) of the selection memory mat (MB0 to MB7), in the memory cell array 9. Subsequently, as described in the seventh embodiment, the charge sharing is carried out between the memory gate electrode (MG1) of the selection memory block (MB0) and those (MG1) of the non-selection memory blocks (MB1 to MB7) to reduce the voltage of the memory gate electrode (MG1) of the selection memory block (MB0). Then, as described in the third embodiment with reference to FIG. 15, the charge sharing is carried out between the memory gate electrodes (MG1 to MG8) in the selection memory block (MB0). However, when the voltage of the memory gate electrode (MG1) of the selection memory block (MB0) can be sufficiently reduced by reducing the voltage applied to the memory gate electrodes (MG1 to MG8) in the non-selection memory mat (MB8 to MB15), and the charge sharing between the memory gate electrodes (MG1 to MG8) in the non-selection memory mat (MB8 to MB15) and their counterparts (MG1 to MG8) in the selection memory mat (MB0 to MB7), the voltage reduction and the charge sharing between the selection memory block (MB0) and the non-selection memory block (MB1 to MB7), as described in the seventh embodiment with reference to FIG. 50, are not necessary. Also, the charge sharing between the memory gate electrodes (MG1 to MG8) in the selection memory block (MB0), as described in the third embodiment with reference to FIG. 15, is not necessary.

The eighth embodiment describes the voltage reduction of the memory gate electrode for the erase operation. In further aspect of the present invention, for example, the charge sharing operation can be applied to the voltage boost of the memory gate electrode for the write operation.

The structure of the switch transistor SW:B in the memory block according to the eighth embodiment is described as similar to that according to the third embodiment. However, same effect can be obtained obviously when the structure and/or operation according to the first or second embodiment is used.

### Ninth Embodiment

### Charge Sharing between Selection Mat and Non-Selection Mat→Charge Sharing 2 between Selection Block and Non-Selection Block

The operation of a ninth embodiment is similar to that of the eighth embodiment in that the voltage for the erase operation is reduced by the charge sharing between memory gate electrodes in different mats. However, the structure of a switch transistor according to the ninth embodiment is different from that according to the eighth embodiment.

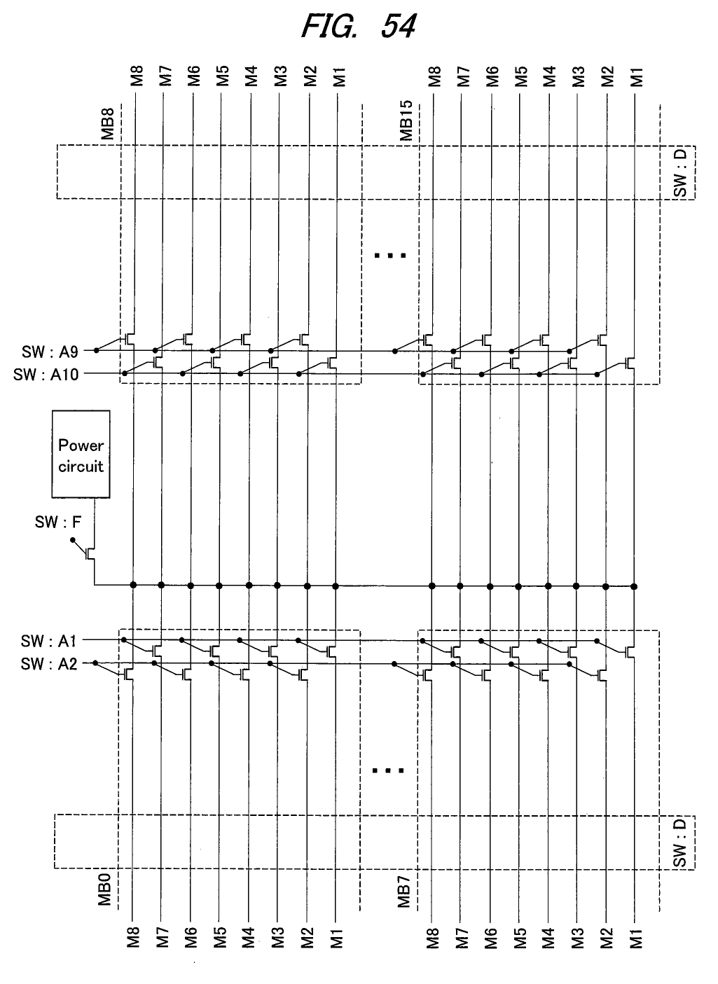

FIG. 54 is an equivalent circuit diagram of a memory cell array according to the ninth embodiment. The circuit shown in FIG. 54 is different from that in FIG. 52 of the eighth embodiment in that, in the circuit in FIG. 54, a switch transistor SW:F is provided between the power supply circuit and the memory cell array (including two memory mats) instead of the switch transistors SW:E that connects the corresponding memory gate electrodes between different mats. Thus, in the structure of the ninth embodiment, the power supply circuit and the memory cell array can be disconnected as a whole. Also, the structure of the switch transistors SW:A and SW:D is similar to that shown in FIG. 52 in the eighth embodiment.

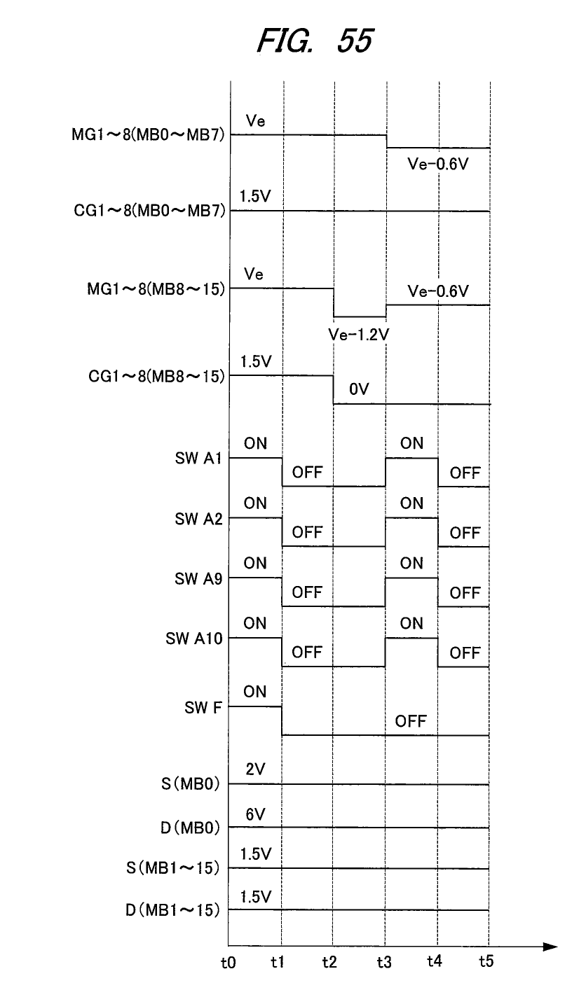

Next, the charge sharing between two different memory mats having above structure will be described. FIG. 55 is a timing chart showing a part of the erase operation of the non-volatile semiconductor memory device according to the ninth embodiment. Some steps in the erase operation according to the ninth embodiment are similar to that described with reference to FIGS. 50 and 15. Therefore, regarding to FIG. 55, the reduction of voltage applied to the memory gate electrodes in the non-selection memory mat (MB8 to MB15) and the charge sharing operation between the selection memory mat (MB0 to MB7) and the non-selection memory mat (MB8 to MB15) will be described.

As shown in FIG. 55, at time t0, the switch transistors SW:A1 to SW:A2 and SW:A9 to SW:A10 and switch transistor SW:F are in ON state, and a voltage of Ve is applied to the memory gate electrodes (MG1 to MG8) (metal wirings M1 to M8) of the memory blocks (MB0 to MB15) via the power circuit. A voltage of 1.5V is applied to all control gate electrodes (CG1 to CG8) including those (CG1 to CG8) in the non-selection memory mat (memory blocks MB8 to MB15) and those (CG1 to CG8) in the selection memory mat (memory blocks MB0 to MB7). A voltage of 1.5V is applied to the source S and the drain D of the memory blocks (MB1t to MB15) except the selection memory block (MB0) included in the selection memory mat (memory mat 13a), while a voltage of 2V is applied to the source S and a voltage of 6V is applied to the drain D, of the selection memory block (MB0) included in the selection memory mat (memory mat 13a).

At time t1, the switch transistor SW:F is turned into OFF state to disconnect the memory cell array and the power supply circuit. The switch transistors SW:A1 to SW:A2 and SW:A9 to SW:A10 are turned into OFF state to turn all memory gate electrodes (MG1 to MG8) included in the selection memory mat (memory mat 13a) and the non-selection memory mat (memory mat 13b) into floating state.

At time t2, the potential of all control gate electrodes (CG1 to CG8) included in the non-selection memory mat (MB8 to MB15) is reduced from 1.5V to 0V. Thereby, the potential of all memory gate electrodes (MG1 to MG8) in the non-selection memory mat (MB8 to MB15) is reduced to Ve−1.2V by capacitive coupling.

At time t3, the switch transistors SW:A1 to SW:A2 and SW:A9 to SW:A10 are turned into ON state to share charges between the memory gate electrodes (MG1 to MG8) in the memory mat 13a and their counterparts (MG1 to MG8) in the memory mat 13b. Thereby, the potential of all memory gate electrodes (MG1 to MG8) in the selection memory mat (MB0 to MB7) including the selection block is reduced to Ve−0.6V.

At time t4, the switch transistors SW:A1 to SW:A2 and SW:A9 to SW:A10 are turned into OFF state. Thus, the voltage applied to the memory gate electrodes (MG1 to MG8) in the non-selection memory mat (MB8 to MB15) is reduced, then the charge sharing is carried out between the memory gate electrodes (MG1 to MG8) in the non-selection memory mat (MB8 to MB15) and their counterparts (MG1 to MG8) in the selection memory mat (MB0 to MB7), in the memory cell array 9. Thereby, the voltage of the memory gate electrodes (MG1 to MG8) in the selection memory mat (MB0 to MB7) can be reduced.

Subsequently, for example, the voltage reduction and the charge sharing is carried out between the selection memory block (MB0) and non-selection memory blocks (MB1 to MB7) included in the same memory mat (MB0 to MB7), as described in the seventh embodiment. Then, the charge sharing is carried out between memory gate electrodes (MG1 to MG8) in the selection memory block (MB0) to carry out the erase operation of the memory gate electrode (MG1) in the selection memory block (MB0). The operation according to the ninth embodiment is characterized in that the erase operation is carried out after three steps of the voltage reduction and the charge sharing, in a manner similar to the eighth embodiment.

The erase operation using the sequence as above can further reduce the potential of the memory gate electrode (MG1) compared to the seventh or third embodiment. Therefore, the memory gate electrode (MG1) can have high potential even when lower voltage is generated by the charge pump circuit for negative voltage supply. As a result, the size of the charge pump circuit and the area of chip can be reduced. In other words, the potential of the memory gate electrode (MG1) in the selection memory block (MB0) is sufficiently reduced by the voltage reduction and the charge sharing in three steps. Thereby, after that, it is possible to decrease loads which are imposed on the charge pump circuit to reduce the voltage of the memory gate electrode (MG1) in the selection memory block (MB0) to the erase voltage. Therefore, since loads which are imposed on the charge pump circuit can be reduced or lightened, it is possible to make the size of the charge pump circuit small, and to reduce the area of the chip.

In the ninth embodiment, the voltage applied to the memory gate electrodes (MG1 to MG8) in the non-selection memory mat (MB8 to MB15) is reduced, then, the charge sharing is carried out between the memory gate electrodes (MG1 to MG8) in the non-selection memory mat (MB8 to MB15) and their counterparts (MG1 to MG8) in the selection memory mat (MB0 to MB7) to reduce the voltage of the memory gate electrodes (MG1 to MG8) of the selection memory mat (MB0 to MB7), in the memory cell array 9. Subsequently, the charge sharing is carried out between the memory gate electrode (MG1) of the selection memory block (MB0) and those (MG1) of the non-selection memory block (MB1 to MB7) to reduce the voltage of the memory gate electrode (MG1) of the selection memory block (MB0), as described in the seventh embodiment. Then, the charge sharing is carried out between the memory gate electrodes (MG1 to MG8) in the selection memory block (MB0), as described in the third embodiment with reference to FIG. 15. However, when the voltage of the memory gate electrode (MG1) can be sufficiently reduced by the reduction of the voltage applied to the memory gate electrodes (MG1 to MG8) in the non-selection memory mat (MB8 to MB15) and the charge sharing between memory gate electrodes (MG1 to MG8) of the non-selection memory mat (MB8 to MB15) and their counterparts (MG1 to MG8) of the selection memory mat (MB0 to MB7), the voltage reduction and the charge sharing between the selection memory block (MB0) and the non-selection memory block (MB1 to MB7), as described in the seventh embodiment with reference to FIG. 50, is not necessary. Furthermore, the charge sharing between the memory gate electrodes (MG1 to MG8) in the selection memory block (MB0) is not necessary, such as that described in the third embodiment with reference to FIG. 15.

The ninth embodiment describes the voltage reduction of the memory gate electrode for the erase operation. In further aspect of the present invention, for example, the charge sharing operation can be applied to the voltage boost of the memory gate electrode for performing the write operation.

The structure of the switch transistor SW:B in the memory block according to the ninth embodiment is similar to that according to the third embodiment. However, same effect can be obtained obviously when the structure and/or operation according to the first or second embodiment are/is used.

### Tenth Embodiment

### Use of FN Erase in the First to Fourth and Seventh to Ninth Embodiments

Difference between a tenth embodiment and the first to fourth and seventh to ninth embodiments is method of data erase operation. In the first to fourth and seventh to ninth embodiments, the erase operation is carried out by hot hole injection induced by band-to-band tunneling to a nitride silicon film that is used as a charge accumulation film. In the tenth embodiment, the erase operation is carried out by FN (Fowler-Nordheim) tunnel current. That is, in the first to fourth and seventh to ninth embodiments, the electrons accumulated in the charge accumulation film is canceled by hot hole injection from the semiconductor substrate to the film, to carry out the erase operation. In the tenth embodiment, the electrons accumulated in the charge accumulation film are discharged from the film to the semiconductor substrate by FN tunnel current, to carry out the erase operation. In this erase operation using FN tunnel current, the potential of the memory gate electrode can be reduced according to the invention, to ensure high potential of the memory gate electrode even when lower voltage is generated by the charge pump circuit for negative voltage supply. In other words, the potential of the memory gate electrode can be reduced by a method exactly identical to that used in the first to fourth and seventh to ninth embodiments. The reduced voltage applied to the memory gate electrode is used as erase voltage by which the erase operation is possible in the charge pump circuit for negative voltage supply to discharge the electrons accumulated in the charge accumulation film made from nitride silicon film to the semiconductor substrate by the FN tunnel current. At this time, a voltage of 0V is applied to the source region/drain region (diffusion layer). Thus, the voltage reduction by the voltage reduction and the charge sharing according to the present invention can be effectively applied to the erase operation that uses the FN tunnel current as described in the tenth embodiment. That is, the voltage reduction according to the present invention can be used in the erase operation using FN tunnel current, to reduce the voltage generated by the charge pump circuit for negative power supply voltage, resulting in the reduction of the size of the charge pump circuit.

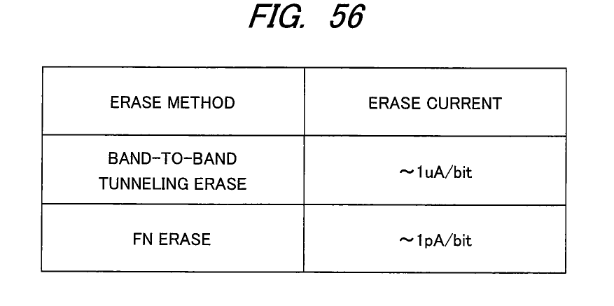

FIG. 56 shows erase current per cell required for the erase operation using FN tunnel current, and that required for the erase operation using band-to-band tunneling. As shown in FIG. 56, it can be understood that the erase current necessary for the erase operation using the FN tunnel current is very small, namely about 1/1000 of that necessary for the erase operation using band-to-band tunneling. The erase operation using FN tunnel current has following advantages. (1) The erase operation can be carried out more rapidly because the larger number of cells can be erased simultaneously; (2) the area of the non-volatile semiconductor memory device (module) can be reduced because a source of erase current is not necessary.

### Eleventh Embodiment

### Example in which Negative Voltage is Applied to Control Gate Electrode in the First to Fourth and Seventh to Ninth Embodiment

In an eleventh embodiment, a case in which a negative voltage is applied to the control gate electrode will be described. In the above first to fourth and seventh to ninth embodiments, minimum value of a voltage applied to the control gate electrode is 0V. However, in order to suppress the off-leak current of the non-selection cell at read operation by scaling of the memory cell, a negative voltage (Vcg) may be applied to the control gate electrode of the non-selection cell. In this case, a voltage reduction larger (from 1.5V to Vcg) than 1.5V (from 1.5V to 0V) can be achieved in the voltage reduction of the control gate electrode, in the voltage reduction operation described in the first to fourth and seventh to ninth embodiments. Thus, a larger potential shift can be obtained for the control gate electrode at the time of the voltage reduction of the memory gate electrode. This configuration can obtain following effects: (1) higher negative potential can be generated, or (2) less potential of Ve can be applied to the memory gate electrode at the beginning.

### Twelfth Embodiment

### Device Structure 1 of Switch Transistor

In a twelfth embodiment, a device structure of a switch transistor will be described.

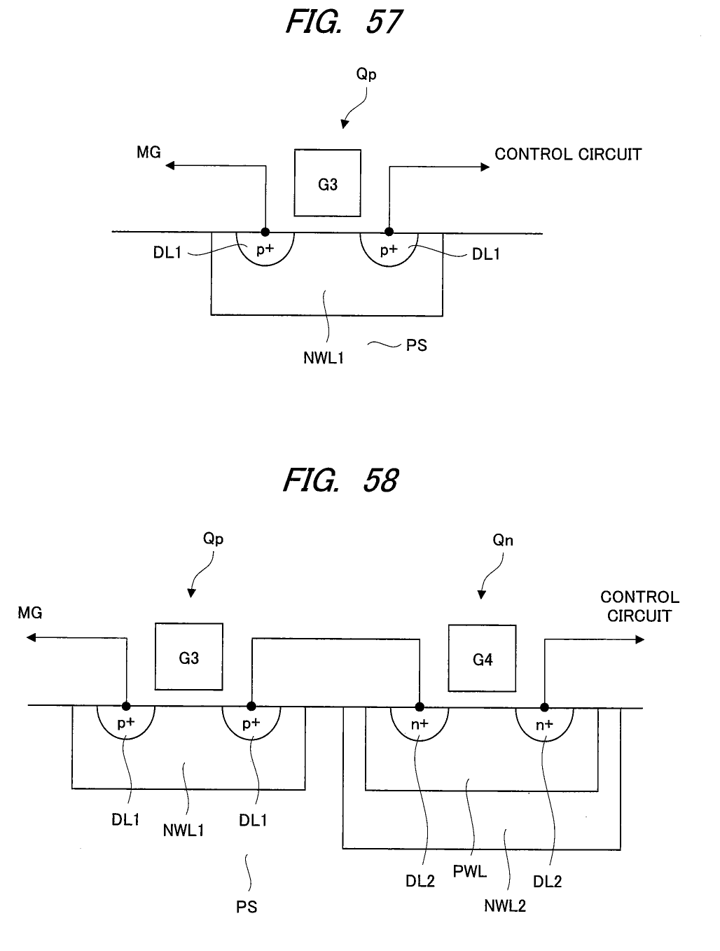

FIG. 57 illustrates an example of MOSFET structure of a switch transistor that uses capacitive coupling for the voltage reduction only when a negative polarity voltage is applied to the memory gate electrode (MG) in a p-type silicon substrate PS and an n-type well NWL, in a case where either a positive or negative polarity voltage may be applied thereto. The switch transistor provided between a control circuit and a memory gate electrode (MG) comprises a p channel type MOSFET Qp.

The structure of a p channel type MOSFET Qp will be described concretely. As shown in FIG. 57, an n-type well NWL1 comprising an n-type semiconductor region (semiconductor region in which n-type impurity such as phosphate or arsenic is introduced) is formed in a p-type silicon substrate PS. In this n-type well NWL1, a pair of diffusion layers DL1 used as a source region and a drain region of a p-channel type MOSFET is formed. These diffusion layers DL1 comprise p-type semiconductor regions in which p-type impurity such as boron (B) is introduced. A gate electrode G3 is formed on the silicon substrate PS between the pair of diffusion layer DL1 via a gate dielectric (not shown). The source region (the diffusion layer DL1 on the left side) of the switch transistor (p-channel type MOSFET Qp) having the structure as above is connected to the memory gate electrode (MG), and the drain region (the diffusion layer DL1 on the right side) of the switch transistor (p-channel type MOSFET Qp) is connected to the control circuit.

Next, the operation of the switch transistor (p-channel type MOSFET Qp) will be described.

First, a case wherein a negative polarity voltage is applied to the memory gate electrode, that is, a case wherein the voltage reduction operation in the negative bias direction is carried out for the memory cell connected to the memory gate electrode, will be described. In this case, a predetermined voltage is applied to the gate electrode G3 of the switch transistor (p-channel type MOSFET Qp) to turn the switch transistor (p-channel type MOSFET Qp) into ON state. When a negative polarity voltage is supplied from the control circuit, the negative voltage is supplied to the memory gate electrode (MG) via the drain region and the source region of the switch transistor (p-channel type MOSFET Qp). Therefore, a negative polarity voltage is applied to the memory gate electrode (MG) when the switch transistor (p-channel type MOSFET Qp) is in ON state. Then, the switch transistor (p-channel type MOSFET Qp) is turned into OFF state to turn the memory gate electrode (MG) into floating state. The potential of the control gate electrode adjacent to the memory gate electrode (MG) is changed to generate capacitive coupling. By this capacitive coupling, the potential applied to the memory gate electrode (MG) is reduced. Then, the charge sharing is carried out by eclectically connecting the memory gate electrode (MG) of which voltage has been reduced and the memory gate electrode to be erased. Thereby, the potential applied to the memory gate electrode to be erased can be reduced.

On the contrary, a case wherein a positive polarity voltage is applied to the memory gate electrode, that is, a case wherein voltage boost in the positive bias direction is carried out for the memory cell connected to the memory gate electrode, will be described. In this case, a predetermined voltage is applied to the gate electrode G3 of the switch transistor (p-channel type MOSFET Qp) to turn the switch transistor (p-channel type MOSFET Qp) into ON state. When a positive polarity voltage is supplied from the control circuit, the positive polarity voltage is supplied to the memory gate electrode via the drain region and the source region of the switch transistor (p-channel type MOSFET Qp). Therefore, a positive polarity voltage is applied to the memory gate electrode (MG) when the switch transistor (p-channel type MOSFET Qp) is in ON state. Then, the switch transistor (p-channel type MOSFET Qp) needs to be turned into OFF state to turn the memory gate electrode (MG) into floating state. This operation might cause problem when the switch transistor comprises a p-channel type MOSFET. That is, when a positive polarity voltage is applied from the control circuit, the pn junction between the drain region (p-type semiconductor region) and n-type well NWL1 of the switch transistor (p-channel type MOSFET Qp) is biased in the forward direction. Under this condition, current flows from the drain region to the n-type well NWL1 even when the switch transistor (p-channel type MOSFET Qp) is in OFF state. Furthermore, since a positive polarity voltage is applied to the memory gate electrode (MG) until the switch transistor (p-channel type MOSFET Qp) is turned into OFF state, the pn junction between the source region (p-type semiconductor region) and n-type well NWL1 of the switch transistor (p-channel type MOSFET Qp) is also biased in the forward direction. Therefore, current flows from the source region of the switch transistor (p-channel type MOSFET Qp) to the n-type well NWL1. Thereby, since current flows from the source region connected to the memory gate electrode (MG) to the n-type well NWL1 even when the switch transistor (p-channel type MOSFET Qp) is in OFF state, it is difficult to keep the memory gate electrode (MG) in floating state when a positive polarity voltage is supplied from the control circuit. In other words, when the switch transistor comprises a p-channel type MOSFET Qp, the memory gate electrode (MG) cannot be kept in floating state when a positive polarity voltage is supplied from the control circuit (the voltage applied to the memory gate (MG) is lowered), even if the switch transistor (p-channel type MOSFET Qp) is in OFF state. Therefore, it is difficult to boost the voltage in the positive bias direction for the memory cell connected to the memory gate electrode (MG). As described, when the switch transistor comprises a p-channel type MOSFET Qp, it will be understood that only the voltage reduction in negative bias direction is effective for the memory cell connected to the memory gate electrode.

### Thirteenth Embodiment

### Device Structure 2 of the Switch Transistor

In the twelfth embodiment, a case wherein the switch transistor comprises a p-channel type MOSFET was described. In a thirteenth embodiment, a case wherein the switch transistor comprises a p-channel type MOSFET and an n-channel type MOSFET will be described.

FIG. 58 illustrates an example of MOSFET structure of a switch transistor that uses capacitive coupling for the voltage reduction when a negative polarity voltage is applied to the memory gate electrode (MG) and for the voltage boost when a positive polarity voltage is applied thereto, when either positive or negative polarity voltage may be applied thereto, in the p-type silicon substrate PS. The switch transistor provided between the control circuit and the memory gate electrode (MG) comprises a p-channel type MOSFET Qp and an n-channel type MOSFET Qn serially connected to each other in series.

First, the structure of a p-channel type MOSFET Qp will be described concretely. As shown in FIG. 58, an n-type well NWL1 comprising an n-type semiconductor region (semiconductor region in which n-type impurity such as phosphate or arsenic is introduced) is formed in a p-type silicon substrate PS. A pair of diffusion layers DL1 that are used as a source region and a drain region of the p-channel type MOSFET is formed in the n-type well NWL1. These diffusion layers DL1 comprise p-type semiconductor regions in which p-type impurity such as boron (B) is introduced. A gate electrode G3 is formed on the silicon substrate PS between the pair of diffusion layers DL1 via a gate dielectric (not shown). In this switch transistor (p-channel type MOSFET Qp) having above structure, the source region (diffusion layer DL1 on the left side) is connected to the memory gate electrode (MG) and the drain region (diffusion layer DL1 on the right side) of the switch transistor (p-channel type MOSFET Qp) is connected to a source region of an n-channel type MOSFET Qn which will be described below.

Next, the structure of the n-channel type MOSFET Qn will be described. As shown in FIG. 58, an n-type well NWL2 comprising an n-type semiconductor region (semiconductor region in which n-type impurity such as phosphate or arsenic is introduced) is formed in the p-type silicon substrate PS. A p-type well PWL is formed in the n-type well NWL2, and a pair of diffusion layer DL2 that are used as a source region and a drain region of the n-channel type MOSFET are formed in the p-type well PWL. The diffusion layers DL2 comprise an n-type semiconductor region in which n-type impurity such as phosphate (P) or arsenic (As) is introduced. A gate electrode G4 is formed on the silicon substrate PS between the pair of diffusion layers DL2 via a gate dielectric (not shown). The source region (diffusion layer DL2 on the left side) of the n-channel type MOSFET Qn having above structure is connected to the drain region (the diffusion layer DL1) of the p-channel type MOSFET Qp, and the drain region (the diffusion layer DL2 on the right side) of the n-channel type MOSFET Qn is connected to the control circuit.

Next, the operation of the switch transistor (p-channel type MOSFET Qp and n-channel type MOSFET Qn) will be described. First, a case wherein a negative polarity voltage is applied to the memory gate electrode, that is, a case wherein the voltage reduction operation in the negative bias direction is carried out for the memory cell connected to the memory gate electrode, will be described. In this case, a predetermined voltage is applied to the gate electrode G3 of the p-channel type MOSFET Qp to turn the p-channel type MOSFET Qp into ON state. Furthermore, a predetermined voltage is applied to the gate electrode G4 of the n-channel type MOSFET Qn to turn the n-channel type MOSFET Qn into ON state.

When a negative polarity voltage is supplied from the control circuit under this condition, the negative polarity voltage is supplied to the memory gate electrode (MG) via the switch transistor (p-channel type MOSFET Qp and n-channel type MOSFET). Therefore, a negative polarity voltage is applied to the memory gate electrode (MG) when the switch transistors (p-channel type MOSFET Qp and n-channel type MOSFET Qn) are in ON state. Then, the p-channel type MOSFET Qp is turned into OFF state to turn the memory gate electrode (MG) into floating state. The potential of the control gate electrode adjacent to the memory gate electrode (MG) is changed to generate capacitive coupling. By the capacitive coupling, the potential applied to the memory gate electrode (MG) is reduced. Then, the charge sharing is carried out by electrically connecting the memory gate (MG) of which voltage has been reduced and the memory gate to be erased. Thus, the potential applied to the memory gate electrode to be erased can be reduced.

When p-channel type MOSFET Qp is turned into OFF state to turn the memory gate electrode (MG) into floating state, the pn junction between the drain region (n-type semiconductor region) and the p-type well PWL of the n-channel type MOSFET Qn is applied with the bias in forward direction because a negative polarity voltage is applied from the control circuit to the drain region (n-type semiconductor region) of the n-channel type MOSFET Qn. For this reason, leak current flows between the drain region (n-type semiconductor region) and the p-type well PWL of the n-channel type MOSFET Qn. However, in the structure of the thirteenth embodiment, an n-type well NWL2 is provided between the p-type well PWL and the p-type silicon substrate PS. This structure restrains or prevents leak current from flowing to the silicon substrate PS.

Next, a case wherein a positive polarity voltage is applied to the memory gate electrode, that is, a case wherein voltage boost in the positive bias direction is carried out for the memory cell connected to the memory gate electrode will be described. In this case, a predetermined voltage is applied to the gate electrode G3 of the p-channel type MOSFET Qp to turn the p-channel type MOSFET Qp into ON state. Furthermore, a predetermined voltage is applied to the gate electrode G4 of the n-channel type MOSFET Qn to turn the n-channel type MOSFET Qn into ON state.

When a positive polarity voltage is supplied from the control circuit under this condition, the positive polarity voltage is supplied to the memory gate electrode (MG) via the switch transistor (p-channel type MOSFET Qp and n-channel type MOSFET Qn). Therefore, a positive polarity voltage is applied to the memory gate electrode (MG) when the switch transistor (p-channel type MOSFET Qp and n-channel type MOSFET Qn) is in ON state. Then, the n-channel type MOSFET Qn is turned into OFF state to turn the memory gate electrode (MG) into floating state. The potential of the control gate electrode adjacent to the memory gate electrode (MG) is changed to generate capacitive coupling. By this capacitive coupling, the potential applied to the memory gate electrode (MG) is boosted. Then, the charge sharing is carried out by electrically connecting the memory gate electrode (MG) of which voltage has been boosted and the memory gate electrode to be written. Thereby, the potential applied to the memory gate electrode to be written can be boosted.

In the thirteenth embodiment, the switch transistor comprises an n-channel type MOSFET Qn and a p-channel type MOSFET Qp serially connected to each other. Thus, the memory gate electrode (MG) to which a positive polarity voltage is applied can be kept in floating condition, where a positive polarity voltage is maintained, by turning the n-channel type MOSFET Qn into OFF state. That is, in the n-channel MOSFET Qn, when a positive polarity voltage is applied from the control circuit, the bias of the opposite direction is applied to the pn junction between the drain region (n-type semiconductor region) and p-type well PW of the n-channel type MOSFET Qn, and to the pn junction of between the source region (n-type semiconductor region) and p-type well PW of the n-channel type MOSFET Qn. Therefore, the memory gate electrode (MG) connected to the source region of the n-channel type MOSFET Qn via the p-channel type MOSFET Qp can be kept in floating state with a positive polarity voltage supplied from the control circuit, when the n-channel type MOSFET Qn is in OFF state. In other words, since a bias in opposite direction is applied to the pn junction between the source region (n-type semiconductor region) and the p-type well PWL of the n-channel type MOSFET Qn, only little current flows, if any.

As described above, by adopting a structure in which the switch transistor comprises a p-channel type MOSFET Qp and an n-channel type MOSFET Qn serially connected to each other, the capacitive coupling can be used for voltage reduction when a negative polarity voltage is applied, and the capacitive coupling also can be used for voltage boost when a positive polarity voltage is applied by the capacitive coupling, in a structure wherein either negative or positive polarity voltage is applied to the memory gate electrode (MG).

The invention can be preferably applied to the non-volatile semiconductor memory device.

In the foregoing, the invention made by the inventors of the present invention has been concretely described based on the embodiments. However, it is needless to say that the present invention is not limited to the foregoing embodiments and various modifications and alterations can be made within the scope of the present invention.

1. A non-volatile semiconductor memory device comprising:
a semiconductor substrate;
a first charge accumulation film formed on the semiconductor substrate;
a first gate electrode formed on the first charge accumulation film;
a second gate electrode formed adjacent to the first gate electrode; and
a control circuit to control the potential of the first and second gate electrodes, wherein,
at the time of data erase operation which corresponds to the amount of charges accumulated in the first charge accumulation film,
the control circuit operates to supply a first potential to the first gate electrode and a second potential to the second gate electrode respectively,
thereafter, the control circuit operates to turn the first gate electrode into floating state, and,
thereafter, the control circuit operates to supply a fourth potential lower than the second potential to the second gate electrode so as to make the first gate electrode have a third potential lower than the first potential.

2. The non-volatile semiconductor memory device according to claim 1 further comprising:
a pair of semiconductor regions which are used as a source and a drain of a first transistor containing the first gate electrode in the semiconductor substrate, wherein
the second gate electrode is adjacent to the side of the first gate electrode via a dielectric, and disposed between the pair of the semiconductor regions on the semiconductor substrate.

3. The non-volatile semiconductor memory device according to claim 1 further comprising:
a second charge accumulation film formed on the semiconductor substrate;
a third gate electrode formed on the second charge accumulation film; and,
a fourth gate electrode formed adjacent to the third gate electrode, wherein
the operation by the control circuit to supply the first potential to the first gate electrode comprises,
an operation of the control circuit to supply a fifth potential to the third gate electrode and a sixth potential to the fourth gate electrode respectively,
thereafter, an operation of the control circuit to turn the third gate electrode into floating state,
thereafter, an operation of the control circuit to supply an eighth potential lower than the sixth potential to the fourth gate electrode so as to make the third gate electrode have a seventh negative potential lower than the fifth potential, and,
thereafter, the control circuit and the first and third gate electrodes are electrically connected by the operation of the control circuit.

4. The non-volatile semiconductor memory device according to claim 2 further comprising:
a second charge accumulation film formed on the semiconductor substrate;
a third gate electrode formed on the second charge accumulation film; and,
a fourth gate electrode formed adjacent to the third gate electrode, wherein
the operation by the control circuit to supply the first potential to the first gate electrode comprises,
an operation of the control circuit to supply a fifth potential to the third gate electrode and a sixth potential to the fourth gate electrode respectively,
thereafter, an operation of the control circuit to turn the third gate electrode into floating state,
thereafter, an operation of the control circuit to supply an eighth potential lower than the sixth potential to the fourth gate electrode so as to make the third gate electrode have a seventh negative potential lower than the fifth potential, and,
thereafter, the control circuit and the first and third gate electrodes are electrically connected by the operation of the control circuit.

5. The non-volatile semiconductor memory device according to claim 1, wherein
the first and second gate electrodes are provided in a memory cell array region, and
no circuit for generating negative voltage is provided outside of the memory cell array region.

6. The non-volatile semiconductor memory device according to claim 3, wherein
the first to fourth gate electrodes are provided in the memory cell array region, and
no circuit for generating negative voltage is provided outside of the memory cell array region.

7. The non-volatile semiconductor memory device according to claim 2 further comprising:
a third charge accumulation film formed on the semiconductor substrate;
a fifth gate electrode formed on the third charge accumulation film; and
a sixth gate electrode formed adjacent to the fifth gate electrode, wherein
after the first gate electrode has a third potential, the control circuit operates to electrically connect the first and the fifth gate electrodes to make the fifth gate electrode have a ninth potential,
thereafter, the control circuit operates to turn the fifth gate electrode into floating state, and
thereafter, the control circuit operates to reduce the potential of the sixth gate electrode to make the fifth gate electrode have a negative tenth potential lower than the ninth potential.

8. The non-volatile semiconductor memory device according to claim 1 further comprising:
a fourth charge accumulation film formed on the semiconductor substrate;
a seventh gate electrode formed on the fourth charge accumulation film; and
a pair of semiconductor regions to be a source and a drain of a first transistor containing the first gate electrode in the semiconductor substrate, wherein
the second gate electrode is disposed on the side of the first gate electrode via a dielectric,
the seventh gate electrode is disposed on the side of the second gate electrode via a dielectric,
the second and seventh gate electrodes are disposed between the pair of the semiconductor regions on the semiconductor substrate, and
the second potential of the second gate electrode is a potential boosted by boosting the potential of the seventh gate electrode.

9. The non-volatile semiconductor memory device according to claim 1, wherein
the first and second gate electrodes are gate electrodes which are included in different memory cells and constitute different word lines, and those word lines are adjacent word lines to each other.

10. The non-volatile semiconductor memory device according to claim 1, wherein
the first charge accumulation film is a nitride silicon film.

11. A non-volatile semiconductor memory device comprising:
a semiconductor substrate;
a first charge accumulation film formed on the semiconductor substrate;
a first gate electrode formed on the first charge accumulation film;
a second gate electrode formed adjacent to the first gate electrode;
a second charge accumulation film formed on the semiconductor substrate;
a third gate electrode formed on the second charge accumulation film;
a fourth gate electrode formed adjacent to the third gate electrode; and
a control circuit to control the potential of the first, second, third and fourth electrodes, wherein
at rewrite operation of the data corresponding to the charges accumulated in the second charge accumulation film,
the control circuit operates to supply a first potential to the first gate electrode, a second potential to the second gate electrode, a third potential to the third date electrode and a fourth potential to the fourth gate electrode respectively,
the control circuit operates to turn the first and third gate electrodes into floating state,
the control circuit operates to supply a sixth potential to the second gate electrode to make the first gate electrode have a fifth potential,
thereafter, the control circuit operates to electrically connect the first and third gate electrodes to make the first and third gate electrodes have a seventh potential which is an intermediate potential between the third and sixth potentials,
thereafter, the control circuit operates to electrically disconnect the third and first gate electrodes to turn the first and third gate electrodes into floating state,
thereafter, the control circuit operates to supply a ninth potential to the fourth gate electrode to make the third gate electrode have an eighth potential,
the ninth potential is higher than the fourth potential when the sixth potential is higher than the second potential, and,
the ninth potential is lower than the fourth potential when the sixth potential is lower than the second potential.

12. The non-volatile semiconductor memory device according to claim 11, further comprising:
a third charge accumulation film formed on the semiconductor substrate;
a fifth gate electrode formed on the third charge accumulation film; and
a sixth gate electrode formed adjacent to the fifth gate electrode, wherein
the control circuit operates to electrically connect the third and fifth gate electrodes to make the fifth gate electrode have a tenth potential,
thereafter, the control circuit operates to electrically disconnect the third and fifth gate electrodes to turn the third and fifth gate electrodes into floating state, and
the control circuit operates to supply a twelfth potential to the sixth gate electrode to make the fifth gate electrode have an eleventh potential.

13. The non-volatile semiconductor memory device according to claim 12, wherein
the first to sixth gate electrodes are provided in one memory mat,
the memory mat includes a plurality of fourth charge accumulation films except the first to third charge accumulation films, a plurality of seventh gate electrodes respectively formed on the plurality of fourth charge accumulation films, and a plurality of eighth gate electrodes formed adjacent to the seventh gate electrodes, and
the control circuit repeats an operation to electrically connect/disconnect the plurality of seventh gate electrodes and other seventh gate electrodes, and an operation to change the potential of the eighth gate electrodes adjacent to the seventh gate electrodes to change the potential of the seventh gate electrodes, on the plurality of seventh and eighth gate electrodes in the memory mat, to make the data corresponding to the volume of the charges accumulated in the first to fourth charge accumulation films become to same data.

14. The non-volatile semiconductor memory device according to claim 12, wherein
the first and second gate electrodes are included in one memory cell,
the third and fourth gate electrodes are included in one memory cell, and
the fifth and sixth gate electrodes are included in one memory cell.

15. The non-volatile semiconductor memory device according to claim 14, wherein
the first and second gate electrodes constitute a split gate type memory cell,
the third and fourth gate electrodes constitute a split gate type memory cell,
the fifth and sixth gate electrode constitute a split gate type memory cell, and,
the first to third charge accumulation films are nitride silicon films.

16. The non-volatile semiconductor memory device according to claim 15, wherein
the rewrite operation is an erase operation,
the first to sixth gate electrodes are provided in a memory cell array region, and
no circuit for generating negative voltage is provided outside of the memory cell array region.

17. A non-volatile semiconductor memory device comprising:
a semiconductor substrate;
a first charge accumulation film formed on the semiconductor substrate;
a first gate electrode formed on the first charge accumulation film;
a second gate electrode formed adjacent to the first gate electrode;
a second charge accumulation film formed on the semiconductor substrate;
a third gate electrode formed on the second charge accumulation film;
a fourth gate electrode formed adjacent to the third gate electrode;
a first switch to turn the first gate electrode into floating state; and
a second switch to turn the second gate electrode into floating state.

18. A non-volatile semiconductor memory device according to claim 17 further comprising:
a third switch to electrically connect the first and third gate electrodes.

19. (canceled)

20. (canceled)
